(19) United States
(12) Patent Application Publication
(10) Pub. No.: US 2026/0352224 A1
(43) Pub. Date: Nov. 5, 2026

(54) DATA CONVERTER BASED ON SEMICONDUCTOR DEVICES

(71) Applicant: Seoul National University R&DB FOUNDATION, Seoul (KR)

(72) Inventors: Jong-Ho LEE, Seoul (KR); Jonghyun KO, Seoul (KR); Jiseong IM, Seoul (KR)

(21) Appl. No.: 19/529,084

(22) Filed: Feb. 3, 2026

Related U.S. Application Data
(60) Provisional application No. 63/755,373, filed on Feb. 7, 2025.

(51) Int. Cl. H03M 1/46

(52) U.S. Cl. CPC H03M 1/462

(57) ABSTRACT

Provided is a data converter based on semiconductor devices. The data converter includes K bit processing units configured to correspond one-to-one with K bits constituting a digital code and sequentially connected in a pipeline structure. Each of the bit processing units includes: a signal generation module including a semiconductor device having a threshold voltage or conductance set according to a position of a corresponding bit; a signal transfer module configured to output one of a bit-level input voltage and a bit-level residual voltage according to an output selection signal; a signal conversion module configured to convert the bit-level residual voltage into a binary signal and output the binary signal; and a mode selection module configured to control a signal path according to an operation mode selection signal so that the data converter operates as one of an analog-to-digital converter and a digital-to-analog converter.

### TECHNICAL FIELD

The present invention relates to a data converter, and more particularly, to a data converter based on semiconductor devices configured by arranging semiconductor devices having different threshold voltages in a pipeline form, so that the data converter can be implemented in a small area, can operate with low power, and can be used in various applications including a neuromorphic system to improve performance.

### BACKGROUND ART

An Analog-to-Digital Converter ADC is an electronic device that converts an analog signal into a digital signal. Signals such as temperature and voltage sensed by sensors in nature are analog signals. An ADC circuit converts the above-described analog signals into digital signals that can be processed by electronic devices such as a computer and a control device and outputs the digital signals. Recently, as advanced electronic devices such as IoT and neuromorphic systems have been widely commercialized, the demand for ADCs having low-power and small-area characteristics has further increased. According to such demands, ADCs having various structures have been developed.

U.S. Patent Application Publication No. 2009-0091483 discloses a Flash ADC structure as one of the ADC types. FIG. 1 is a structural diagram illustrating the Flash ADC scheme. As illustrated in FIG. 1, the flash ADC performs an ADC operation that converts an analog signal into a digital signal by using a comparator bank composed of 2^{K} comparators. The comparators of the flash ADC receive a reference voltage corresponding to a reference value and an analog voltage to be determined. The comparators of the flash ADC compare magnitudes of the two input voltages and output a result as a digital code. The flash ADC having such a structure continues to be widely used in applications requiring high speed and low latency.

However, the conventional flash ADC having the above-described structure uses a large number of comparators, and thus a large amount of power consumption occurs during operation. Therefore, the conventional flash ADC is difficult to use in low-power applications. In addition, since the conventional flash ADC uses a large number of comparators, a large chip area is required. Accordingly, the ADC having the above-described structure is difficult to use in compact applications.

In addition, the resolution of the conventional flash ADC is limited according to the number of comparators used. Therefore, in order to increase the resolution of the flash ADC, the number of comparators needs to be increased, and accordingly there is a problem in that the circuit structure of the ADC becomes complicated and the manufacturing cost increases as well as the power consumption increases.

As described above, when the number of bits increases in the ADC having the above-described structure, the device area and power consumption increase exponentially, and it is difficult to use the ADC in applications requiring high resolution.

U.S. Pat. No. 7,965,218 discloses a Successive Approximation Register SAR ADC structure. FIG. 2 is a structural diagram illustrating the SAR ADC scheme according to the related art. As illustrated in FIG. 2, the SAR ADC performs an ADC operation by using one comparator, a DAC, a logic circuit, and a register. In general, bits are sequentially determined starting from a Most Significant Bit MSB. The SAR ADC uses one comparator, and the DAC uses a plurality of capacitors having different sizes and controls an output value of the DAC using a charge sharing principle. A result of the bit determination up to a current time is stored in the register, and according to the result, the DAC adjusts a reference voltage of the comparator through the logic circuit. By repeating the above-described process, bit values are determined from the MSB to a Least Significant Bit LSB.

The SAR ADC having the above-described structure provides high resolution, but still has a problem in that a large circuit area and a large amount of power consumption are required.

### SUMMARY OF THE INVENTION

In order to solve the above-described problems, an object of the present invention is to provide a data converter that is configured to perform an analog-to-digital conversion operation and a digital-to-analog conversion operation by using a structure in which memory devices having different threshold voltages are connected in a pipeline form, so that circuit area and power consumption can be significantly reduced and the data converter can be used in various systems including a neuromorphic network.

In order to achieve the above-described technical object, a pipeline-type data converter according to a first aspect of the present invention is a data converter configured to convert an analog signal into a digital code composed of K bits (where K is a natural number) or to convert a digital code into an analog signal, based on semiconductor devices, the data converter comprising K bit processing units sequentially connected in a pipeline form and configured to correspond one-to-one with the K bits constituting the digital code. Each bit processing unit includes: a signal generation module including a semiconductor device having a threshold voltage or a conductance set according to a position of a corresponding bit in the digital code, the signal generation module being configured such that a bit level input voltage is applied to the semiconductor device and a bit level residual voltage B_RES determined according to a relationship between the bit level input voltage B_IN and a threshold voltage Vₜₕ of the memory device is generated; and a signal transfer module including one or more switching devices and configured to output, as a bit level output voltage, one of the bit level input voltage and the bit level residual voltage of the signal generation module according to an output selection signal. A bit level input voltage of a bit processing unit processing a most significant bit MSB of the digital code is a preset starting voltage or an analog signal to be converted, and bit level input voltages of the remaining bit processing units are bit level output voltages of signal transfer modules included in bit processing units of a previous stage.

The pipeline-type data converter according to the first aspect having the above-described features is a Digital-to-Analog Converter DAC configured to convert a digital code into an analog signal, wherein a bit level input voltage of a bit processing unit processing a most significant bit MSB of the digital code is a preset starting voltage, and a signal transfer module of each bit processing unit receives, as an output selection signal, a code of a corresponding bit in the digital code or an inverted code of the code, and a bit level output voltage of a signal transfer module of a bit processing unit processing a least significant bit LSB of the digital code forms an analog signal corresponding to the digital code.

The pipeline-type data converter according to the first aspect having the above-described features is an Analog-to-Digital Converter ADC configured to convert an analog signal into a digital code, wherein each bit processing unit further includes a signal conversion module configured to convert a bit level residual voltage B_RES output from the signal generation module into a binary signal and output the binary signal; a bit level input voltage of a bit processing unit processing a most significant bit of the digital code is an analog signal; and the signal conversion module of each bit processing unit is preferably configured to output a code of a corresponding bit in the digital code and provide the code to the signal transfer module as an output selection signal.

The pipeline-type data converter according to the first aspect having the above-described features is a converter configured to selectively operate as one of an ADC and a DAC, wherein each bit processing unit further includes: a signal conversion module configured to convert a bit level residual voltage output from the signal generation module into a binary signal and output the binary signal; and a mode selection module disposed between the signal conversion module and the signal transfer module, configured to receive an operation mode selection signal, and configured to control a signal path according to the received operation mode selection signal so that the converter operates as one of an ADC and a DAC. The mode selection module is preferably configured such that, when an analog-to-digital conversion mode is selected, an output signal of the signal conversion module for an analog signal to be converted is provided to the signal transfer module as an output selection signal, and when a digital-to-analog conversion mode is selected, a code of a corresponding bit of a digital code to be converted is provided to the signal transfer module as an output selection signal.

In the pipeline-type data converter according to the first aspect having the above-described features, each bit processing unit preferably further includes a stabilization module composed of a device or a circuit configured to provide a constant current to the signal generation module and disposed between an output terminal of the signal generation module and a ground terminal.

In the pipeline-type data converter according to the first aspect having the above-described features, the signal generation module of the bit processing unit is preferably composed of a semiconductor device having a non-volatile memory characteristic capable of varying a threshold voltage or a conductance, or composed of one of a flash memory device, a resistive change memory device, a phase change memory device, a ferroelectric memory device, a magnetoresistive memory device, and a Field Effect Transistor.

In the pipeline-type data converter according to the first aspect having the above-described features, the signal conversion module of the bit processing unit is preferably composed of one of an inverter circuit, a buffer circuit, and a sense amplifier having a preset switching voltage.

In the pipeline-type data converter according to the first aspect having the above-described features, the signal transfer module preferably includes: a first switching device configured to output a bit level residual voltage of the signal generation module as a bit level output voltage; a second switching device configured to output a bit level input voltage of the bit processing unit as the bit level output voltage; and a selection circuit configured to drive one of the first switching device and the second switching device according to an output selection signal, wherein the output selection signal of the selection circuit is preferably one of a code of a corresponding bit in the digital code and a binary signal obtained by converting the bit level residual voltage of the signal generation module.

In the pipeline-type data converter according to the first aspect having the above-described features, the first and second switching devices of the signal transfer module are more preferably composed of one of a transmission gate TG or a single pass gate.

In the pipeline-type data converter according to the first aspect having the above-described features, the mode selection module is preferably configured to include one of a digital multiplexer, an analog multiplexer, and a tri-state buffer, or to be composed of a combination of a plurality of NAND gate devices.

In the pipeline-type data converter according to the first aspect having the above-described features, the pipeline-type data converter preferably further includes a threshold voltage adjustment module configured to adjust or reset threshold voltages of memory devices included in signal generation modules of the bit processing units.

In order to achieve the above-described technical object, a pipeline-type data converter according to a second aspect of the present invention is a data converter configured to convert an analog signal into a digital code composed of K bits (where K is a natural number) based on semiconductor devices, the data converter including: a plurality of conversion stages sequentially connected in a pipeline form and configured to convert a stage input voltage into a digital code to generate a partial digital code; and an output code generation module configured to generate a final digital code corresponding to the analog signal based on the partial digital codes output from the plurality of conversion stages. Each conversion stage includes: a signal generation module configured to generate the partial digital code by converting the stage input voltage into a digital code using semiconductor devices having different threshold voltages or conductances; and a signal transfer module configured to generate a stage output voltage based on the stage input voltage and a digital conversion result of the signal generation module. A stage input voltage of a first conversion stage is an analog signal to be converted, and stage input voltages of the remaining conversion stages are stage output voltages generated in conversion stages of a previous stage.

In the pipeline-type data converter according to the second aspect having the above-described features, the partial digital code generated by the signal generation module of each conversion stage is a thermometer code, and each conversion stage preferably further includes a code conversion module configured to convert the partial digital code in a thermometer code form generated from the signal generation module into a binary code and output the binary code.

In the pipeline-type data converter according to the second aspect having the above-described features, the output code generation module is more preferably configured to generate the final digital code based on binary codes output from code conversion modules included in the plurality of conversion stages.

In the pipeline-type data converter according to the second aspect having the above-described features, the stage output voltage is preferably a residual voltage that has not been converted by the partial digital code from the stage input voltage in the signal generation module included in the corresponding conversion stage.

In the pipeline-type data converter according to the second aspect having the above-described features, the signal generation module included in the conversion stage preferably includes a plurality of semiconductor devices having different threshold voltages or conductances, a stage level voltage is applied to the plurality of semiconductor devices, each of the plurality of semiconductor devices is configured to generate a binary value based on a relationship between the stage level voltage and the threshold voltage, and the signal generation module is configured to generate a partial digital code based on the binary values respectively generated by the plurality of semiconductor devices.

In the pipeline-type data converter according to the second aspect having the above-described features, the signal generation module included in the conversion stage is preferably composed of a semiconductor device having a non-volatile memory characteristic capable of varying a threshold voltage or a conductance, or composed of one of a flash memory device, a resistive change memory device, a phase change memory device, a ferroelectric memory device, a magnetoresistive memory device, and a Field Effect Transistor.

In the pipeline-type data converter according to the second aspect having the above-described features, the signal transfer module included in the conversion stage preferably includes one of a digital multiplexer, an analog multiplexer, and a tri-state buffer configured to select one of a plurality of input channels by a selection signal and provide the selected input channel to a single output channel.

In the pipeline-type data converter according to the second aspect having the above-described features, the selection signal is a partial digital code according to a digital conversion result of the signal generation module, signals input through a plurality of input channels respectively include voltages output from a plurality of semiconductor devices included in the signal generation module and the stage input voltage, and the output channel is more preferably configured to detect a residual voltage that has not been converted by the partial digital code from the stage input voltage based on the selection signal and output the detected residual voltage as the stage output voltage.

In order to achieve the above-described technical object, a successive approximation type data converter according to a third aspect of the present invention is a successive approximation register SAR type data converter configured to convert an analog signal, which is an input signal, into a digital code composed of K bits (where K is a natural number) based on semiconductor devices, the data converter including: a signal generation module including a plurality of semiconductor devices arranged to correspond to respective bits of the digital code and having different threshold voltages, wherein the input signal is applied to one selected from among the plurality of semiconductor devices, and the signal generation module is configured to generate a bit level output voltage for the input signal based on a relationship between the input signal and the threshold voltage; a signal conversion module configured to convert the bit level output voltage output from the signal generation module into a binary signal and output a binary value for a corresponding bit of the digital code; a SAR register configured to store the binary value output from the signal conversion module at a corresponding bit position of the digital code; and a SAR controller configured to generate a control signal for sequentially selecting the semiconductor devices included in the signal generation module based on bit values stored in the SAR register according to a preset successive approximation logic, wherein the input signal is sequentially applied to the semiconductor devices included in the signal generation module according to the control signal of the SAR controller, so that the signal generation module sequentially generates bit level output voltages for the input signal.

In the successive approximation type data converter according to the third aspect having the above-described features, the semiconductor devices included in the signal generation module are connected in parallel, and according to the control signal of the SAR controller, the input signal is applied only to a selected semiconductor device, and a turn-off signal is applied to the remaining semiconductor devices that are not selected, so that the bit level output voltage of the signal generation module is preferably generated based on a relationship between the threshold voltage of the selected semiconductor device and the applied input signal.

In the successive approximation type data converter according to the third aspect having the above-described features, the semiconductor devices included in the signal generation module are connected in series to form a string structure, and according to the control signal of the SAR controller, the input signal is applied to a selected semiconductor device, and a pass voltage is applied to the remaining semiconductor devices that are not selected, so that the bit level output voltage of the signal generation module is preferably generated based on a relationship between the threshold voltage of the selected semiconductor device and the applied input signal.

In the successive approximation type data converter according to the third aspect having the above-described features, the data converter preferably further includes a stabilization module including devices configured to provide a constant current to semiconductor devices included in the signal generation module, the stabilization module being disposed between an output terminal of the signal generation module and a ground terminal.

In the successive approximation type data converter according to the third aspect having the above-described features, the semiconductor devices included in the signal generation module are preferably composed of a semiconductor device having a non-volatile memory characteristic capable of varying a threshold voltage or a conductance, or composed of one of a flash memory device, a resistive change memory device, a phase change memory device, a ferroelectric memory device, a magnetoresistive memory device, a field effect transistor, and a ferroelectric tunnel junction FTJ device.

In the successive approximation type data converter according to the third aspect having the above-described features, the signal conversion module is preferably composed of one of an inverter circuit, a buffer circuit, and a sense amplifier having a preset switching voltage.

In the successive approximation type data converter according to the third aspect having the above-described features, the signal generation module preferably further includes a plurality of selection devices connected in one-to-one correspondence with the plurality of semiconductor devices.

In the successive approximation type data converter according to the third aspect having the above-described features, the SAR controller preferably applies the input signal to the plurality of semiconductor devices included in the signal generation module and sequentially activates selection devices connected to semiconductor devices selected according to the control signal, so that the signal generation module sequentially outputs bit level output voltages for the input signal.

In the successive approximation type data converter according to the third aspect having the above-described features, the selection device of the signal generation module is preferably composed of a transmission gate TG or a switching device.

The data converter according to the present invention having the above-described configuration has a threshold voltage or conductance control structure based on non-volatile memory devices, and thus can be naturally combined with analog computation characteristics required in in-memory computing and neuromorphic systems. Accordingly, the structure according to the present invention can be effectively applied to next-generation artificial intelligence and neuromorphic computing systems.

In addition, in the data converter according to the present invention, since the semiconductor devices included in the signal generation module have non-volatile memory characteristics capable of varying a threshold voltage or a conductance, a threshold voltage corresponding to each bit can be precisely set. Through this, linearity and accuracy of an analog output voltage corresponding to a digital code can be improved.

Meanwhile, the data converters according to the first, second, third, and fourth embodiments of the present invention have a structure in which K bit processing units are sequentially connected in a pipeline form, and thus operations of the respective bit processing units proceed stepwise based on a clock signal. Accordingly, an overall conversion delay time is reduced, so that high-speed digital-to-analog conversion is possible.

In addition, in the data converters according to the first, second, third, and fourth embodiments of the present invention, each bit processing unit generates a bit level residual voltage based on a difference between a threshold voltage of a semiconductor device and a bit level input voltage, and thus analog conversion can be performed without using a conventional weighted resistor network or a large-scale capacitor array. Accordingly, a circuit structure is simplified and implementation complexity is reduced.

In addition, the data converters according to the first and third embodiments of the present invention adopt a structure in which an input voltage of the MSB bit processing unit is set as a starting voltage IN, and thus a reference offset of a final output voltage DACOUT can be circuitously adjusted. Accordingly, various output voltage ranges can be supported while maintaining the same circuit structure.

In addition, in the data converters according to the first, second, third, and fourth embodiments of the present invention, the signal transfer module selectively transmits only one of a bit level input voltage and a bit level residual voltage according to a digital code, and thus unnecessary current consumption can be suppressed. Accordingly, power consumption of the overall system can be reduced.

In addition, the structure of the data converter according to the first, second, third, and fourth embodiments of the present invention can be implemented not only as a DAC structure that converts a digital code into an analog signal, but also can be extended and applied to an Analog-to-Digital Converter ADC structure by using the same threshold voltage-based comparison and residual transmission principle. Accordingly, both a DAC and an ADC can be implemented based on a single basic architecture.

In particular, the data converter according to the fourth embodiment of the present invention performs digital conversion of an analog input signal stepwise in a plurality of conversion stages, thereby enabling high-resolution digital conversion exceeding a resolution limit achievable in a single conversion stage. In addition, in an initial conversion stage, an approximate magnitude of the input signal is determined, and in subsequent conversion stages, finer voltage variations are converted based on a residual voltage, so that an accurate digital representation from higher bits to lower bits can be achieved overall.

In addition, since the data converter according to the fourth embodiment of the present invention implements resolution distributed across a plurality of stages, the circuit scale of each conversion stage can be relatively simplified. Accordingly, the circuit area is reduced, design complexity is alleviated, and integration density in a large-scale integrated circuit can be improved.

Meanwhile, the data converters according to the fifth, sixth, and seventh embodiments of the present invention generate a bit level output voltage based on a relationship between a threshold voltage of a semiconductor device and a magnitude of an input signal, and thus a voltage comparison operation is immediately performed by physical characteristics of the semiconductor device. Accordingly, high-speed analog-to-digital conversion is possible compared to a conventional operation-based comparison method.

In addition, the data converters according to the fifth, sixth, and seventh embodiments of the present invention generate a bit level output voltage based on a relationship between a threshold voltage of a semiconductor device and a magnitude of an input signal, and thus the comparison operation is directly performed by physical characteristics of the semiconductor device. Accordingly, high-speed successive approximation conversion is possible without using a separate high-speed comparator.

In addition, in the data converters according to the fifth, sixth, and seventh embodiments of the present invention, since threshold voltages of the semiconductor devices can be programmed and erased, variations in characteristics due to process variations, temperature changes, or aging can be compensated. In addition, by adjusting a threshold voltage distribution, resolution characteristics or nonlinear characteristics of the ADC can be controlled by design.

In addition, in the data converters according to the fifth, sixth, and seventh embodiments of the present invention, since the structure replaces comparator and DAC functions with a semiconductor device-based signal generation module while maintaining a basic structure of a SAR register and a SAR controller, existing SAR ADC design assets can be utilized as they are.

In addition, in the data converters according to the fifth, sixth, and seventh embodiments of the present invention, resolution can be easily extended by increasing the number of semiconductor devices included in the signal generation module, and various resolutions and operation modes can be supported by modifying SAR control logic. Due to the above structural features, the data converter according to the present invention can be particularly advantageously applied to a sensor interface, an artificial intelligence accelerator, a neuromorphic system, and an in-memory computing environment requiring low-power and high-speed operation.

### BRIEF DESCRIPTION OF THE DRAWINGS

FIG. 1 is a structural diagram illustrating a Flash ADC scheme according to the related art.

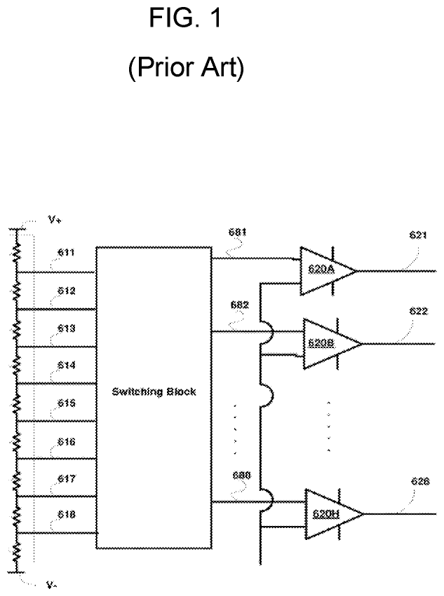

FIG. 2 is a structural diagram illustrating a SAR ADC scheme according to the related art.

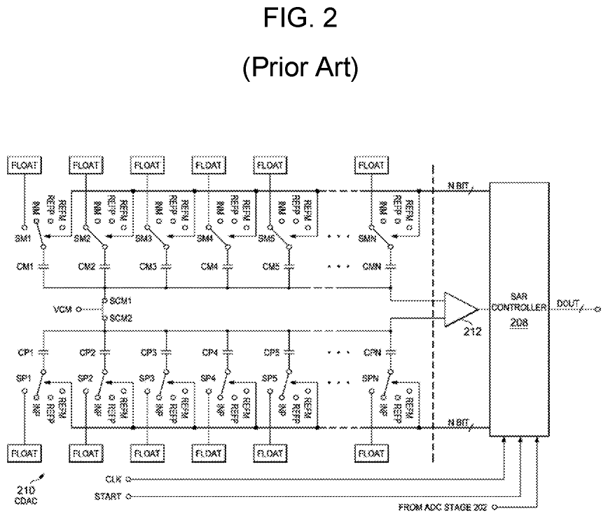

FIG. 3 is a circuit diagram illustrating a structure of a data converter according to a first embodiment of the present invention.

FIG. 4 is a circuit diagram illustrating a data converter according to a second embodiment of the present invention.

FIG. 5 is a circuit diagram illustrating another embodiment of a signal transfer module in the data converter according to the second embodiment of the present invention.

FIG. 6 is a circuit diagram illustrating a structure of a data converter according to a third embodiment of the present invention.

FIG. 7 is a circuit diagram illustrating a data converter according to a fourth embodiment of the present invention.

FIG. 8 is a circuit diagram illustrating an example of a signal generation module 600 included in each conversion stage in the data converter according to the fourth embodiment of the present invention.

FIG. 9 is a circuit diagram illustrating a SAR-type data converter according to the related art.

FIG. 10 is a circuit diagram illustrating a data converter based on SAR logic according to a fifth embodiment of the present invention.

FIG. 11 is a circuit diagram illustrating a successive approximation type data converter according to a sixth embodiment of the present invention.

FIG. 12 is a circuit diagram illustrating a successive approximation type data converter according to a seventh embodiment of the present invention.

### DETAILED DESCRIPTION

A data converter based on semiconductor devices according to the present invention is characterized in that it uses a structure in which semiconductor devices having different threshold voltages are sequentially arranged in a pipeline form. The data converter according to the present invention converts an analog signal, which is an input signal, into a digital code and outputs the digital code, and the digital-to-analog converter according to the present invention converts a digital code, which is an input signal, into an analog signal and outputs the analog signal. In addition, the data converter according to the present invention may include an operation mode selection function so as to be selectively operated as one of an ADC and a DAC. Here, the digital code is composed of a binary code composed of K bits (where K is a natural number). Hereinafter, structures and operations of data converters according to preferred embodiments of the present invention will be described in detail with reference to the accompanying drawings. Meanwhile, for convenience of description, in the present specification, a case in which the semiconductor device is configured as an NMOS-based device will be mainly described. However, this is merely illustrative, and the technical idea of the present invention is not limited thereto. That is, the semiconductor device is not limited to an NMOS-based device and may be implemented with transistor structures of various polarities including a PMOS-based device.

### First Embodiment

Hereinafter, with reference to the accompanying drawings, a structure and operation of a pipeline-type data converter according to a first embodiment of the present invention will be described in detail. The data converter according to the first embodiment of the present invention is a digital-to-analog converter and is characterized in that a digital code is converted into an analog voltage signal and output based on semiconductor devices sequentially connected in a pipeline form. Here, the digital code is composed of a binary code composed of K bits (where K is a natural number). Meanwhile, for convenience of description, in the present specification, a case in which the semiconductor device is configured as an NMOS-based device will be mainly described. However, this is merely illustrative, and the technical idea of the present invention is not limited thereto. That is, the semiconductor device is not limited to an NMOS-based device and may be implemented with transistor structures of various polarities including a PMOS-based device.

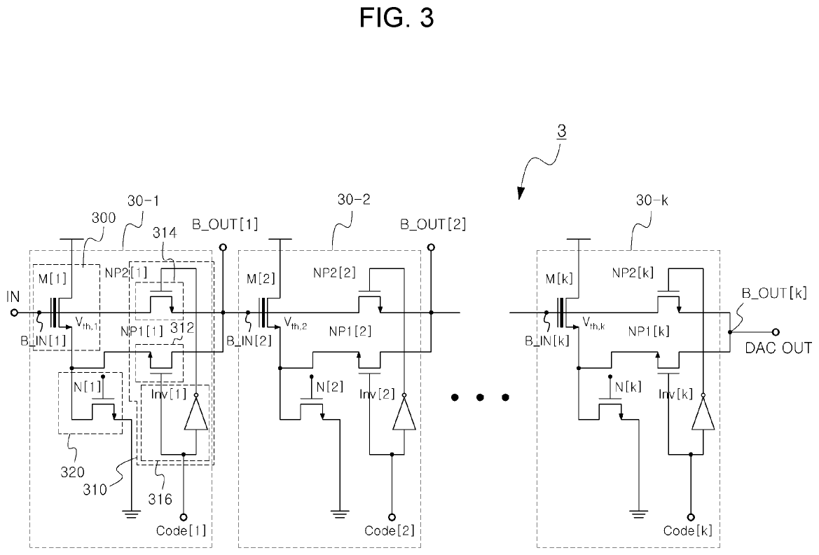

FIG. 3 is a circuit diagram illustrating a structure of a digital-to-analog converter according to the first embodiment of the present invention. Referring to FIG. 3, the digital-to-analog converter 3 according to the first embodiment of the present invention includes K bit processing units 30-1, 30-2, . . . , 30-k connected in a pipeline form. The K bit processing units 30-1, 30-2, . . . , 30-k are configured to correspond one-to-one with K bits constituting a digital code and are sequentially connected in a pipeline form. Each of the bit processing units includes a signal generation module 300 and a signal transfer module 310, and may further include a stabilization module 320.

A bit level input voltage B_IN[1] of a bit processing unit 30-1 processing a most significant bit MSB of the digital code is set to a preset starting voltage IN. Bit level input voltages B_IN[2], B_IN[3], . . . , B_IN[k] of remaining bit processing units 30-2, 30-3, . . . , 30-k except for the MSB bit processing unit 30-1 are sequentially provided with bit level output voltages B_OUT[1], B_OUT[2], . . . , B_OUT[k-1] from signal transfer modules included in bit processing units of a previous stage. In addition, a bit level output voltage B_OUT[k] output from a signal transfer module of a bit processing unit 30-k processing a least significant bit LSB of the digital code forms an output voltage DACOUT of the digital-to-analog converter as an analog signal corresponding to the digital code to be converted.

At this time, the bit level input voltage of the MSB bit processing unit is sequentially transferred to each bit processing unit based on the starting voltage IN in a state in which the voltage is subtracted by a threshold voltage of a semiconductor device included in the signal generation module or maintained according to the digital code Code[1:k], and finally a bit level output voltage B_OUT[k] is generated. Accordingly, the digital-to-analog converter according to the first embodiment of the present invention can adjust an offset of a final output voltage DACOUT using the starting voltage IN. Meanwhile, when the semiconductor device is implemented as a PMOS-based memory device, the voltage may be sequentially transferred to each bit processing unit in a state in which the voltage is increased by the threshold voltage of the semiconductor device or maintained, and finally the bit level output voltage may be generated.

The K bit processing units 30-1, 30-2, . . . , 30-k are configured to correspond one-to-one with K bits constituting a digital code. Signal generation modules 300 of the K bit processing units 30-1, 30-2, . . . , 30-k respectively include semiconductor devices M[1], M[2], . . . , M[k]. The semiconductor devices M[1], M[2], . . . , M[k] included in the bit processing units respectively have threshold voltages Vₜₕ₁, Vₜₕ₂, . . . , Vₜₕₖ determined according to positions of corresponding bits in the digital code. A gate electrode of the semiconductor device of the signal generation module 300 receives a bit level input voltage and may be configured to generate bit level residual voltages B_RES[1], B_RES[2], . . . , B_RES[k] determined according to a relationship between the bit level input voltage and the threshold voltage of the semiconductor device. Here, the bit level residual voltage B_RES may be defined as a difference value between the bit level input voltage and the threshold voltage.

The semiconductor devices M[1], M[2], . . . , M[k] included in the signal generation modules 300 may be composed of semiconductor devices having non-volatile memory characteristics capable of varying threshold voltages or conductances, or may be composed of one of a flash memory device, a resistive change memory device, a phase change memory device, a ferroelectric memory device, a magnetoresistive memory device, and a field effect transistor. In addition, the first semiconductor device M1 may be composed of a two-terminal device such as RRAM, PRAM, or ferroelectric tunnel junction device. Detailed descriptions of various methods for varying the threshold voltage or conductance of the first semiconductor device will be described later.

The operating state of the signal generation module 300, that is, a current driving capability, is determined by a relationship between a threshold voltage Vₜₕ and a bit level input voltage B_IN applied to a gate terminal of the semiconductor device included in the signal generation module 300 having the above-described configuration. Specifically, when the bit level input voltage applied to the semiconductor device included in the signal generation module 300 is greater than the threshold voltage of the semiconductor device, the semiconductor device of the signal generation module 300 is turned on, and accordingly outputs a bit level residual voltage B_RES. On the other hand, when the bit level input voltage applied to the semiconductor device included in the signal generation module 300 is smaller than the threshold voltage of the semiconductor device the semiconductor device of the signal generation module 300 is turned off.

The signal transfer module 310 may include one or more switching devices and may be configured to output one of a bit level input voltage B_IN and a bit level residual voltage B_RES of the signal generation module according to a code Code[1], Code[2], . . . , Code[k] of a corresponding bit in the digital code.

The signal transfer module 310 may include a first switching device 312, a second switching device 314, and a selection circuit 316. The first switching device NP1 312 is disposed between an output terminal of the signal generation module and an output terminal of the bit processing unit and may be configured to output a bit level residual voltage B_RES of the signal generation module to the output terminal of the bit processing unit. The second switching device NP2 314 is disposed between an input terminal and the output terminal of the bit processing unit and may be configured to output a bit level input voltage B_IN of the bit processing unit to the output terminal of the bit processing unit.

The selection circuit 316 may be configured to selectively drive one of the first switching device and the second switching device according to an output selection signal. In this case, a code of a corresponding bit in the digital code is input to the signal transfer module 310 of each bit processing unit and is used as the output selection signal. Accordingly, the output selection signal input to the signal transfer module 310 of each bit processing unit may be composed of a value of the corresponding bit in the digital code Code[1:k] to be converted.

The selection circuits 316 of the signal transfer modules 310 of the K bit processing units may be implemented by inverter devices INV. An output selection signal may be applied to a gate electrode of the first switching device 312 and to an input of an inverter device included in the selection circuit 316, and an output of the inverter device may be applied to a gate electrode of the second switching device 314. Accordingly, the output selection signal is applied to the gate electrode of the first switching device 312, and an inverted signal of the output selection signal is applied to the gate electrode of the second switching device 314, so that one of the first switching device and the second switching device is selectively driven.

The first switching device 312 and the second switching device 314 of the signal transfer module 310 may be composed of one of a transmission gate TG and a single pass gate. The first switching device and the second switching device are selectively driven in a mutually exclusive manner according to the output selection signal. Specifically, when a code Code[1], which is the output selection signal, is ‘1’, the first switching device 312 is driven to an ON state and the second switching device 314 is maintained in an OFF state. Accordingly, by driving the first switching device, a bit level residual voltage B_RES may be applied to the output terminal of the bit processing unit. On the other hand, when the code Code[1], which is the output selection signal, is ‘0’, the first switching device 312 is maintained in the OFF state and the second switching device 314 is driven to the ON state. Accordingly, by driving the second switching device, the bit level input voltage B_IN may be applied to the output terminal of the bit processing unit.

The stabilization module 320 may be composed of devices capable of providing a constant current to the signal generation module and may be disposed between an output terminal of the signal generation module and a ground terminal. The stabilization module 320 may be composed of one of a single MOSFET device, a plurality of MOSFET devices connected in series, a transmission gate device, a resistor, and a non-volatile memory device.

When the stabilization module is composed of a single transistor, stabilization may be improved by increasing Rout.

As described above, the semiconductor devices M[1], M[2], . . . , M[k] included in the signal generation module 300 are composed of devices capable of varying a threshold voltage or a conductance, and depending on a type of the device, the threshold voltage or conductance may be fixedly set in a design stage or may be variably controlled in a driving stage using non-volatile memory characteristics. Accordingly, the semiconductor devices M[1], M[2], . . . , M[k] included in the signal generation module 300 may be implemented as: 1) devices having non-volatile memory characteristics capable of varying the threshold voltage or conductance, or 2) semiconductor devices in which the threshold voltage or conductance is fixedly set by adjusting a coupling ratio or the like in the design stage.

Semiconductor devices having non-volatile memory characteristics that can be used for the signal generation module 300 include a flash memory device, a resistive change memory device, a phase change memory device, a ferroelectric memory device, and a magnetoresistive memory device. Hereinafter, methods for adjusting a threshold voltage or a conductance for each device capable of constituting the semiconductor device of the signal generation module 300 will be briefly described.

A flash memory device can adjust a threshold voltage or a conductance by applying a voltage pulse to inject electrons or holes into a gate insulating layer. The electrons or holes injected into the gate insulating layer influence a channel. By using this characteristic, in the case of an n-channel flash memory device, the threshold voltage of the device can be adjusted by injecting electrons to increase the threshold voltage or injecting holes to decrease the threshold voltage.

A resistive change memory device has a metal-insulator-metal structure, and a conductance can be varied by inducing a resistance change in an intermediate insulating layer by applying a voltage pulse. In this case, a voltage pulse may be applied in a direction that increases the conductance, or a voltage pulse may be applied in a direction that decreases the conductance.

A ferroelectric memory device can change a threshold voltage or a conductance by applying a voltage pulse to a ferroelectric insulating layer to form an electric field in the insulating layer. In the case of a field effect transistor using the ferroelectric insulating layer as a gate insulating layer, an electric field may be formed in a direction that increases conductance in the ferroelectric insulating layer, or the electric field may be adjusted in a direction that decreases conductance. A ferroelectric tunnel junction device can adjust conductance by controlling a tunneling probability of carriers through a direction and strength of the electric field in the ferroelectric insulating layer.

A magnetoresistive memory device may be composed of a fixed layer, an insulating layer, and a free layer, and the fixed layer and the free layer have magnetic properties. A magnetization direction of the fixed layer is fixed, and a magnetization direction of the free layer can be changed. In this case, when a current is applied to the magnetoresistive memory device in a direction from the fixed layer to the free layer, the magnetization direction of the free layer becomes the same as that of the fixed layer, and conductance increases. On the other hand, when a current is applied to the magnetoresistive memory device in a direction opposite to the direction from the fixed layer to the free layer, the magnetization direction of the free layer becomes different from that of the fixed layer, and conductance decreases. In this manner, the conductance of the magnetoresistive memory device can be controlled by using current.

When the signal generation module 300 is composed of a semiconductor device having a gate electrode or a control gate electrode, a threshold voltage of each device may be adjusted in a device and surrounding wiring design (physical layout) stage. As an example of a method therefor, when the device is designed to include components serving as a floating gate and a control gate by adjusting a physical layout in a device design stage, a threshold voltage or a conductance may be set by adjusting a coupling ratio between the gates. In addition, in a case of a device that does not include a floating gate or a charge storage layer, a threshold voltage or a conductance may be set by adjusting coupling between the gate and surrounding metal wiring.

When designing a device constituting the signal generation module 300, if the device is designed to have components serving as a floating gate and a control gate by adjusting a physical layout, a coupling ratio at which a voltage of the control gate is transferred to the floating gate varies according to a spacing or an area ratio between the two gates. Through this, even a semiconductor device having no memory function can set a threshold voltage or a conductance to various desired values.

In the case of a semiconductor device that does not include a floating gate, a threshold voltage may be adjusted by adjusting a coupling ratio between a gate electrode and surrounding electrodes. In this case, the gate electrode is designed to serve as a floating gate, and the surrounding electrodes are designed to serve as control gates. Here, the threshold voltage or conductance may be changed by adjusting the coupling ratio between the floating gate and the control gates.

When the signal generation module 300 is implemented with FET devices having no memory function or devices having non-volatile memory characteristics, it is preferable to increase precision by reducing variation in threshold voltage by using methods such as increasing a gate area relative to a minimum size, including dummy devices, or applying a common centroid technique. Here, the area of the gate determines a length and a width of a channel formed in the device.

When the signal generation module 300 is implemented as a two-terminal device among the above-described devices, driving of the corresponding device may be controlled by connecting an additional switching device. Here, the two-terminal device may be one of RRAM, PCRAM, FTJ, and MTJ, and as an example of the additional switching device, a MOSFET device including a gate terminal may be used.

When the signal generation module 300 is implemented as a device having non-volatile memory characteristics, a threshold voltage adjustment module may be further provided. The threshold voltage adjustment module may be configured to adjust or reset threshold voltages of semiconductor devices included in the signal generation modules of the bit processing units. By using the threshold voltage adjustment module, threshold voltages or conductances of the semiconductor devices included in the signal generation modules may be varied according to bit positions and resolutions of the signal generation modules 300 constituting the converter.

The threshold voltage adjustment module may adjust the digital-to-analog conversion operation by adjusting a threshold voltage or conductance of the semiconductor device included in the signal generation module 300. The threshold voltage adjustment module may basically be configured as a pulse generator, and may operate in a manner of changing a memory state by applying a pulse to the non-volatile memory device constituting the signal generation module 300.

### Second Embodiment

Hereinafter, with reference to the accompanying drawings, a structure and operation of a pipeline-type data converter according to a second embodiment of the present invention will be described in detail. The data converter according to the second embodiment of the present invention is an analog-to-digital converter and is characterized in that an analog signal is converted into a digital code and output based on semiconductor devices sequentially connected in a pipeline form. Here, the digital code is composed of a binary code composed of K bits (where K is a natural number).

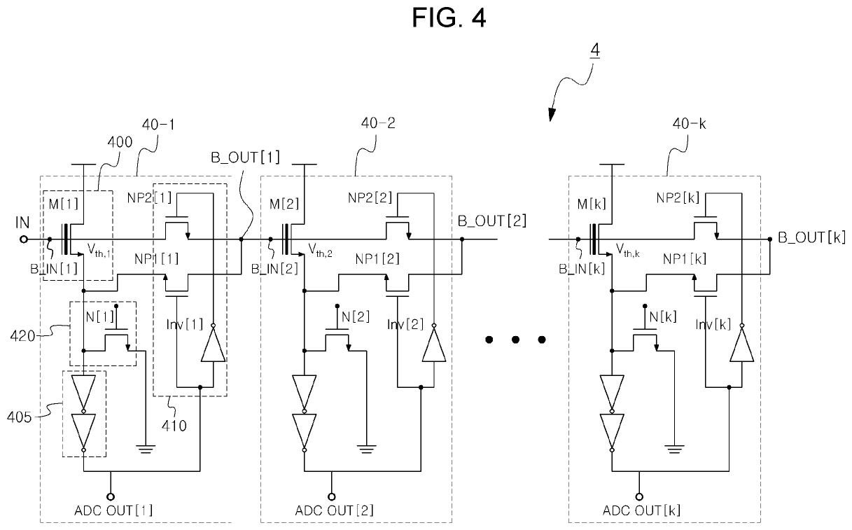

FIG. 4 is a circuit diagram illustrating an analog-to-digital converter according to the second embodiment of the present invention. Referring to FIG. 4, the analog-to-digital converter 4 according to the second embodiment of the present invention includes K bit processing units 40-1, 40-2, . . . , 40-k connected in a pipeline form. The K bit processing units 40-1, 40-2, . . . , 40-k are configured to correspond one-to-one with K bits constituting a digital code and are sequentially connected in a pipeline form. Each of the bit processing units includes a signal generation module 400, a signal transfer module 410, and a signal conversion module 405, and may further include a stabilization module 420.

The bit-level input voltage B_IN[1] of the bit processing unit (MSB bit processing unit; 40-1) that processes the most significant bit MSB of the digital code is applied with the analog signal voltage IN to be converted. The bit-level input voltages B_IN[2], B_IN[3], . . . , B_IN[k] of the remaining bit processing units 40-2, 40-3, . . . , 40-k other than the MSB bit processing unit are sequentially provided with bit-level output voltages B_OUT[1], B_OUT[2], . . . , B_OUT[k−1] output from the signal transfer modules included in the bit processing units of the previous stage. In addition, the input signals applied to the signal transfer modules of the K bit processing units 40-2, 40-3, . . . , 40-k are codes OUT[1], OUT[2], . . . , OUT[k] corresponding to respective bits in the digital code, and the digital code corresponding to the analog signal is completed by combining the codes of the respective bits. In this case, OUT[1] forms the MSB of the digital code, and OUT[k] forms the LSB of the digital code.

The signal generation module 400 includes a semiconductor device M having a threshold voltage Vₜₕ or conductance set according to a position of a corresponding bit in the digital code. The signal generation module 400 is configured such that a bit-level input voltage B_IN is applied to a gate electrode of the semiconductor device, and a bit-level residual voltage B_RES[1], B_RES[2], . . . , B_RES[k], which is determined based on a relationship between the bit-level input voltage and the threshold voltage of the semiconductor device, is generated. Since the structure and operation of the semiconductor devices M[1], M[2], . . . , M[k] included in the signal generation modules 400 are substantially the same as those of the semiconductor devices of the signal generation module according to the first embodiment, a repeated description thereof will be omitted.

The signal conversion module 405 is connected to an output terminal of the signal generation module and is configured to convert a bit-level residual voltage output from the signal generation module into a binary signal to output codes OUT[1], OUT[2], . . . , OUT[k] corresponding to respective bits in the digital code. Meanwhile, the signal conversion module 405 is configured to provide the generated bit code to the signal transfer module.

The signal conversion module 405 is a device having a preset switching voltage and may be composed of one of an inverter circuit, a buffer circuit, and a sense amplifier, and the sense amplifier may be driven in a differential manner. An input terminal of the signal conversion module 405 is connected to a bit line of the semiconductor device included in the signal generation module 400 and is configured to output a binary value determined according to the switching voltage. Meanwhile, when the signal conversion module 405 is composed of an inverter circuit, the performance of the analog-to-digital converter may be improved by changing the number or structure of the inverters or by adjusting a channel width and a channel length of a MOSFET used in the inverter.

The signal transfer module 410 may include one or more switching devices and may be configured to output one of a bit-level input voltage B_IN and a bit-level residual voltage B_RES according to an output selection signal. The signal transfer module 410 may include a first switching device 412, a second switching device 414, and a selection circuit 416.

Since the structures and operations of the signal transfer module 410, the first switching device 412, the second switching device 414, and the selection circuit 416 are substantially the same as those of the signal transfer module according to the first embodiment, a repeated description thereof will be omitted. However, unlike the first embodiment, the output selection signal input to the signal transfer module 410 may be composed of codes OUT[1], OUT[2], . . . , OUT[k] corresponding to respective bits in the digital code output from the signal conversion module 405.

Accordingly, when the code OUT applied as the output selection signal is ‘1’, the first switching device 412 is driven in an ON state, and the second switching device 414 maintains an OFF state. As a result, by the operation of the first switching device, the bit-level residual voltage B_RES may be applied to the output terminal of the bit processing unit. Conversely, when the code OUT applied as the output selection signal is ‘0’, the first switching device 412 maintains the OFF state, and the second switching device 414 is driven in the ON state. As a result, by the operation of the second switching device, the bit-level input voltage B_IN may be applied to the output terminal of the bit processing unit.

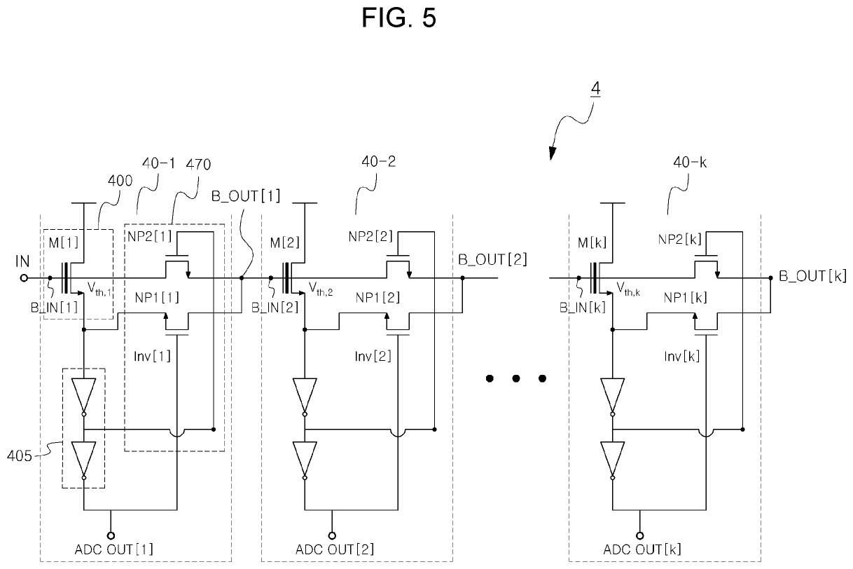

FIG. 5 is a circuit diagram illustrating another embodiment of a signal conversion module and a signal transfer module in the analog-to-digital converter according to the second embodiment of the present invention. Referring to FIG. 5, the signal conversion module 405 may be configured in the same manner as in the first embodiment, but may be further configured to provide a first output selection signal and a second output selection signal. Here, the first output selection signal may be composed of a code corresponding to a respective bit in the digital code, and the second output selection signal may be composed of an inverted code of the first output selection signal. Meanwhile, the signal transfer module 470 may be configured to provide the first and second output selection signals provided from the signal conversion module to first and second switching devices, respectively. The embodiment illustrated in FIG. 5 may operate substantially in the same manner as the embodiment illustrated in FIG. 4.

Since the structure and operation of the stabilization module 420 are substantially the same as those of the stabilization module according to the first embodiment, a repeated description thereof will be omitted. Meanwhile, the ADC according to the second embodiment of the present invention may further include a threshold voltage adjustment module. Since the structure and operation of the threshold voltage adjustment module are also substantially the same as those of the threshold voltage adjustment module according to the first embodiment, a repeated description thereof will be omitted.

### Third Embodiment

Hereinafter, the structure and operation of a pipeline-type data converter according to a third embodiment of the present invention will be described in detail with reference to the accompanying drawings. The data converter according to the third embodiment of the present invention is characterized in that it is configured to select one operation mode of an ADC and a DAC based on semiconductor devices sequentially connected in a pipeline form. Accordingly, when an analog-to-digital conversion mode is selected, the data converter operates as an Analog-to-Digital Converter ADC that converts an analog signal into a digital code and outputs the digital code. Meanwhile, when a digital-to-analog conversion mode is selected, the data converter operates as a Digital-to-Analog Converter DAC that converts a digital code into an analog signal and outputs the analog signal. Here, the digital code is composed of a binary code consisting of K bits (where K is a natural number).

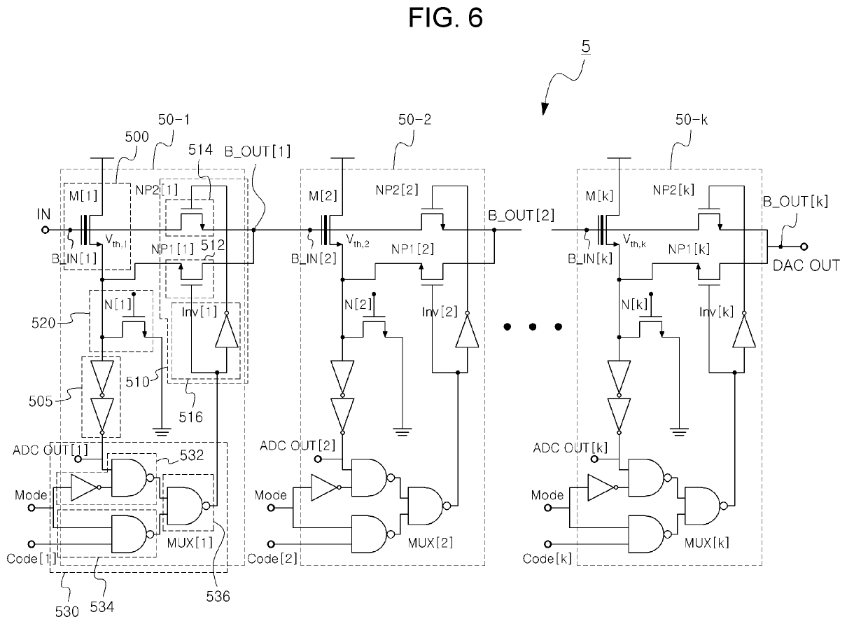

FIG. 6 is a circuit diagram illustrating a structure of a converter according to the third embodiment of the present invention. Referring to FIG. 6, the converter 5 according to the third embodiment of the present invention includes K bit processing units 50-1, 50-2, . . . , 50-k connected in a pipeline form. The K bit processing units 50-1, 50-2, . . . , 50-k are configured to correspond one-to-one with K bits constituting a digital code and are sequentially connected in a pipeline form. Each of the bit processing units includes a signal generation module 500, a signal conversion module 505, a signal transfer module 510, and a mode selection module 530, and may further include a stabilization module 520.

The signal generation modules 500 respectively included in the K bit processing units 50-1, 50-2, . . . , 50-k each include semiconductor devices M[1], M[2], . . . , M[k]. The semiconductor devices M[1], M[2], . . . , M[k] are configured to have threshold voltages Vₜₕ₁, Vₜₕ₂, . . . , Vₜₕₖ or conductances set according to positions of corresponding bits in the digital code. The signal generation module 500 may be configured such that bit-level input voltages B_IN[1], B_IN[2], . . . , B_IN[k] are applied to gate electrodes of the semiconductor devices, and bit-level residual voltages B_RES[1], B_RES[2], . . . , B_RES[k], which are determined based on relationships between the bit-level input voltages and the threshold voltages of the semiconductor devices, are generated and output. Here, each bit-level residual voltage may be defined as a difference value between the bit-level input voltage and the corresponding threshold voltage.

Since the structure and operation of the semiconductor devices M[1], M[2], . . . , M[k] of the signal generation module 500 are substantially the same as those of the semiconductor devices of the signal generation modules according to the first and second embodiments, a repeated description thereof will be omitted.

The bit-level input voltage B_IN[1] of the bit processing unit (MSB bit processing unit; 50-1) that processes the most significant bit MSB of the digital code is applied with either a preset starting voltage or an analog signal voltage IN to be converted. The bit-level input voltages B_IN[2], B_IN[3], . . . , B_IN[k] of the remaining bit processing units 50-2, 50-3, . . . , 50-k other than the MSB bit processing unit correspond to bit-level output voltages B_OUT[1], B_OUT[2], . . . , B_OUT[k−1] output from the signal transfer module of the bit processing unit of a previous stage.

In an analog-to-digital conversion mode, the bit-level input voltage B_IN[1] of the MSB bit processing unit 50-1 is applied with an analog signal IN to be converted, and the K bit processing units may output codes ADCOUT[1], ADCOUT[2], . . . , ADCOUT[k] corresponding to respective bits in the digital code. The data converter according to the present embodiment may combine the codes output from the K bit processing units to complete a digital code ADCOUT[1:k] corresponding to the analog signal. Here, ADCOUT[1] forms the MSB of the digital code, and ADCOUT[k] forms the LSB of the digital code.

Meanwhile, in a digital-to-analog conversion mode, the bit-level input voltage B_IN[1] of the MSB bit processing unit 50-1 is applied with a preset starting voltage IN, and the last bit processing unit 50-k may output an analog signal DACOUT.

The signal conversion module 505 is connected to an output terminal of the signal generation module and may be configured to convert a bit-level residual voltage B_RES output from the signal generation module into a binary signal and output the binary signal as a code ADCOUT corresponding to a respective bit of the digital code. Meanwhile, the signal conversion module 505 is configured to provide codes ADCOUT[1], ADCOUT[2], . . . ADCOUT[k] corresponding to the respective bits of the digital code to the mode selection module 530. Since the configuration and operation of the signal conversion module 505 are substantially the same as those of the signal conversion module according to the second embodiment, a repeated description thereof will be omitted.

The signal transfer module 510 may include one or more switching devices and may be configured to output one of a bit-level input voltage B_IN and a bit-level residual voltage B_RES according to an output selection signal. The signal transfer module 510 may include a first switching device 512, a second switching device 514, and a selection circuit 516. Since the configurations and operations of the signal transfer module 510, the first switching device 512, the second switching device 514, and the selection circuit 516 are substantially the same as those of the signal transfer modules according to the first and second embodiments, a repeated description thereof will be omitted. However, unlike the first and second embodiments, the output selection signal input to the signal transfer module 510 is a signal output from the mode selection module 530. Accordingly, in an analog-to-digital conversion mode, the output selection signal may be composed of codes ADCOUT[1], ADCOUT[2], . . . , ADCOUT[k] corresponding to respective bits of the digital code output from the signal conversion module.

Meanwhile, in a digital-to-analog conversion mode, the output selection signal may be composed of codes Code[1], Code[2], . . . , Code[k] corresponding to respective bits of the digital code to be converted.

Accordingly, when a signal Code[1:k] or ADCOUT[1:k] applied as the output selection signal is ‘1’, the first switching device 512 is turned ON and the second switching device 514 is turned OFF. As a result, by the operation of the first switching device, the bit-level residual voltage may be applied to the output terminal of the bit processing unit. Conversely, when the signal Code[1:k] or ADCOUT[1:k] applied as the output selection signal is ‘0’, the first switching device 512 is turned OFF and the second switching device 514 is turned ON. As a result, by the operation of the second switching device, the bit-level input voltage may be applied to the output terminal of the bit processing unit.

Since the configuration and operation of the stabilization module 520 are substantially the same as those of the stabilization modules according to the first and second embodiments, a repeated description thereof will be omitted. Meanwhile, the converter according to the third embodiment of the present invention may further include a threshold voltage adjustment module. Since the configuration and operation of the threshold voltage adjustment module are also substantially the same as those of the threshold voltage adjustment modules according to the first and second embodiments, a repeated description thereof will be omitted.

The mode selection module 530 is configured to provide an output selection signal to the signal transfer module according to an operation mode selection signal and is disposed between the signal conversion module and the signal transfer module. The operation mode selection signal is configured as a signal for selecting one of an analog-to-digital conversion mode and a digital-to-analog conversion mode.

The mode selection module 530 includes a first input signal path, a second input signal path, and a multiplexer. The first input signal path is composed of circuits configured to provide an output of the signal conversion module to the multiplexer in the analog-to-digital conversion mode. The second input signal path is composed of circuits configured to provide, to the multiplexer, codes corresponding to respective bits of the digital code to be converted in the digital-to-analog conversion mode. The multiplexer is configured to select one of the input signals and provide the selected signal to the signal transfer module. The multiplexer described above may be composed of one of a digital multiplexer, an analog multiplexer, and a tri-state buffer, or may be configured by combining a plurality of NAND gate elements.

The mode selection module 530 having the above-described structure receives an operation mode selection signal and controls signal paths so that the converter operates in one of an analog-to-digital conversion mode and a digital-to-analog conversion mode. Specifically, in the analog-to-digital conversion mode, the mode selection module provides an output signal of the signal conversion module to the signal transfer module as the output selection signal. Conversely, in the digital-to-analog conversion mode, the mode selection module provides codes corresponding to respective bits of the digital code to the signal transfer module as the output selection signal.

Hereinafter, the operation of the data converter according to the third embodiment of the present invention having the above-described configuration will be described in detail.

First, when operating in the digital-to-analog conversion mode, a DAC selection signal and a digital code Code[1:k] are input to the mode selection module of each bit processing unit, and a preset starting voltage IN is applied as the bit-level input voltage BIN[1] of the MSB bit processing unit. Accordingly, each bit processing unit provides codes Code[1], Code[2], . . . , Code[k] corresponding to respective bits of the digital code as output selection signals of the signal transfer module. The signal transfer module then outputs one of the bit-level input voltage BIN and the bit-level residual voltage B_RES according to the output selection signal. Therefore, the bit-level output voltage BOUT[k] of the signal transfer module of the LSB bit processing unit 50-k of the converter serves as an output voltage DACOUT of the DAC, thereby forming an analog signal corresponding to the digital code to be converted.

Meanwhile, when operating in the analog-to-digital conversion mode, an ADC selection signal is input to the mode selection module of each bit processing unit, and an analog signal IN to be converted is applied as the bit-level input voltage B_IN[1] of the MSB bit processing unit. Accordingly, the signal generation module and the signal conversion module of each bit processing unit convert a bit-level residual voltage B_RES into a binary signal and output codes ADCOUT[1], ADCOUT[2], . . . , ADCOUT[k] corresponding to respective bits of the digital code. The mode selection module then provides the codes ADCOUT[1], ADCOUT[2], . . . , ADCOUT[k] corresponding to the respective bits of the digital code to the signal transfer module as output selection signals. Accordingly, the signal conversion modules of the respective bit processing units of the converter output codes ADCOUT[1:k] corresponding to the respective bits of the digital code, and these codes form a digital code corresponding to the analog signal to be converted.

### Fourth Embodiment

Hereinafter, the structure and operation of a pipeline-type data converter based on semiconductor devices according to a fourth embodiment of the present invention will be described in detail with reference to the accompanying drawings. The data converter according to the fourth embodiment of the present invention is an analog-to-digital converter that converts an analog signal into a digital code and outputs the digital code based on semiconductor devices sequentially connected in a pipeline form. In particular, the analog-to-digital converter according to the fourth embodiment of the present invention is characterized in that high resolution is efficiently achieved by stepwise converting an analog input signal into a digital signal through a plurality of conversion stages. Here, the digital code is composed of a binary code consisting of K bits (where K is a natural number).

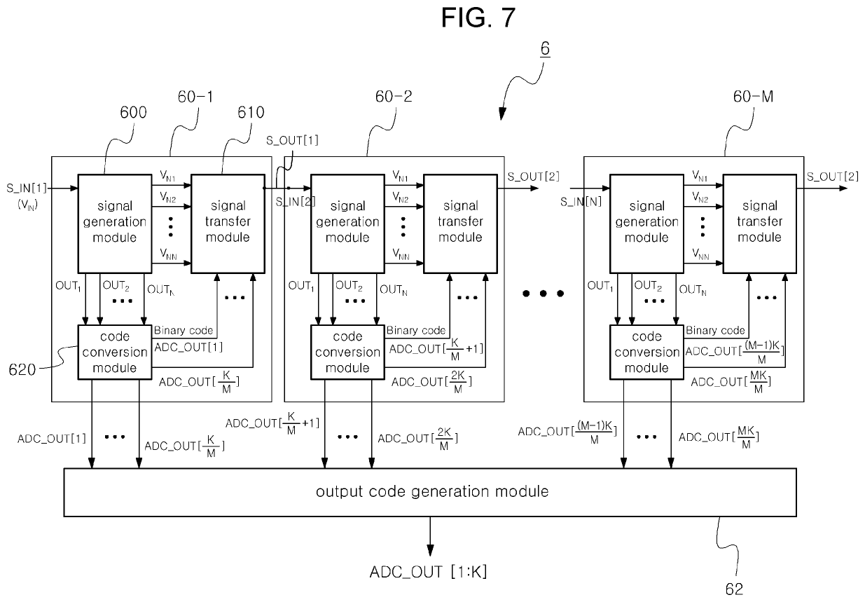

FIG. 7 is a circuit diagram illustrating an analog-to-digital converter according to the fourth embodiment of the present invention. Referring to FIG. 7, the analog-to-digital converter 6 according to the fourth embodiment of the present invention includes M conversion stages 60-1, 60-2, . . . , 60-M connected in a pipeline form and an output code generation module 62. The analog-to-digital converter 6 according to the fourth embodiment of the present invention is configured to divide K bits constituting a digital code into M bit groups according to their order. The M conversion stages 60-1, 60-2, . . . , 60-M are configured to correspond one-to-one with the M bit groups and are sequentially connected in a pipeline form. Each conversion stage 60-1, 60-2, . . . , 60-M includes a signal generation module 600, a signal transfer module 610, and a code conversion module 620, and is configured to generate a binary code by performing digital conversion on a stage input voltage S_IN. The output code generation module 62 is configured to generate a final digital code ADC_OUT[1:K] corresponding to the analog signal VIN based on partial digital codes output from the plurality of conversion stages.

For convenience of description, the present specification exemplarily describes a case in which each of the M conversion stages processes N bits. In this case, the converter according to the present embodiment may provide a resolution of M×N bits. However, this is merely an example for explanation, and the M conversion stages may be configured to process different numbers of bits, respectively. For example, when the M conversion stages process N[1], N[2], . . . , N[M] bits, respectively, the overall resolution of the converter may be

$${Σ}_{i = 1}^{M} N [ i ]$$

bits.

The signal generation module 600 included in the conversion stage includes semiconductor devices having different threshold voltages or conductances. Accordingly, the signal generation module is configured to generate a partial digital code by performing digital conversion of a stage input voltage S_IN using a plurality of semiconductor devices. The partial digital code generated in the signal generation module may be generated in the form of a thermometer code.

The signal transfer module 610 included in the conversion stage is configured to generate a stage output voltage S_OUT based on the stage input voltage and a digital conversion result of the signal generation module. The code conversion module 620 included in the conversion stage is configured to convert a partial digital code OUT[1:N] in the form of a thermometer code generated by the signal generation module into a binary code ADC_OUT[(K/M+1):(2K/M)] and output the binary code.

The stage input voltage S_IN[1] of the first conversion stage 60-1 is applied with an analog signal VIN to be converted. Meanwhile, the stage input voltages S_IN[2], S_IN[3], . . . , S_IN[M] of the remaining conversion stages 60-2 to 60-M, except for the first conversion stage, are sequentially applied with stage output voltages S_OUT[1], S_OUT[2], . . . , S_OUT[M-1] respectively generated from the conversion stage of the previous stage.

Meanwhile, each conversion stage may further include a signal amplification module (not shown). The signal amplification module is disposed at an output end of the signal transfer module 610 and is configured to amplify a residual voltage output from the signal transfer module and then provide the amplified residual voltage to a conversion stage of a next stage. With such a configuration, resolution requirements required for subsequent conversion stages may be relaxed.

In addition, the plurality of conversion stages constituting the analog-to-digital converter according to the fourth embodiment do not necessarily have to be configured as analog-to-digital converters having the same structure. At least some of the conversion stages may be configured to improve overall conversion accuracy by processing the residual voltage using a CMOS-based analog-to-digital converter such as a flash ADC or a SAR ADC.

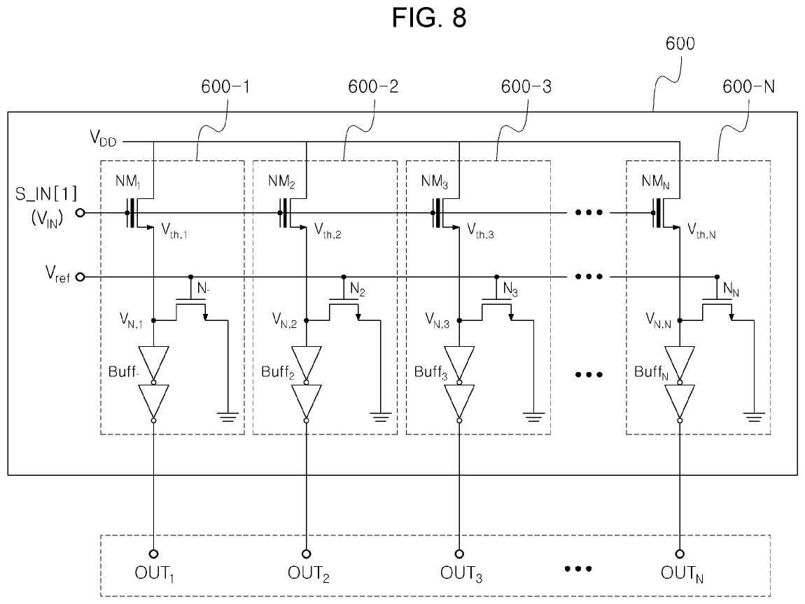

Hereinafter, the structure and operation of the signal generation module 600 will be described in more detail with reference to FIG. 8. FIG. 8 is a circuit diagram illustrating an example of the signal generation module 600 included in each conversion stage in the analog-to-digital converter according to the fourth embodiment of the present invention. Referring to FIG. 8, the signal generation module 600 of the analog-to-digital converter 6 according to the fourth embodiment of the present invention includes a plurality of semiconductor devices having different threshold voltages or conductances and is configured to generate a partial digital code based on voltages output from the semiconductor devices. Meanwhile, for convenience of description, the present embodiment will mainly be described with reference to a case in which the semiconductor devices are NMOS-based devices. However, this is merely illustrative, and the technical concept of the present invention is not limited thereto. That is, the semiconductor devices are not limited to NMOS-based devices and may also be implemented using transistor structures of various polarities including PMOS-based devices.

Each of the plurality of semiconductor devices included in the signal generation module 600 is applied with a stage input voltage to be converted. The plurality of semiconductor devices of the signal generation module 600 are configured to generate binary values corresponding to output voltages determined based on a relationship between the stage input voltage S_IN and the threshold voltage Vₜₕ of the corresponding semiconductor device. Specifically, when the stage input voltage applied to a gate electrode of the semiconductor device is greater than the threshold voltage, an output terminal of the semiconductor device is charged with a voltage corresponding to a difference between the stage input voltage S_IN and the threshold voltage Vₜₕ, and accordingly outputs ‘1’ through a buffer circuit Buff connected to the semiconductor device. Conversely, when the stage input voltage applied to the gate electrode of the semiconductor device is less than the threshold voltage, the semiconductor device is not turned on, and accordingly outputs ‘0’ through the buffer circuit Buff connected to the semiconductor device.

Meanwhile, the semiconductor devices included in the signal generation module included in the conversion stage may be configured as semiconductor devices having non-volatile memory characteristics capable of varying a threshold voltage or conductance, or may be composed of one of a flash memory device, a resistive change memory device, a phase-change memory device, a ferroelectric memory device, a magnetoresistive memory device, and a field effect transistor FET.

Meanwhile, the signal transfer modules 610 of the conversion stages are each configured to output a stage output voltage S_OUT. The stage output voltage S_OUT may be formed as a residual voltage corresponding to a portion of the stage input voltage that has not been converted into a partial digital code in the corresponding conversion stage.

The signal transfer module 610 included in the conversion stage may include one of a digital multiplexer, an analog multiplexer, and a tri-state buffer configured to select one of a plurality of input channels according to a selection signal and provide the selected signal to a single output channel. The selection signal of the signal transfer module may be a binary code provided from the code conversion module 620. The binary code is generated by converting a partial digital code having the form of a thermometer code generated as a digital conversion result of the signal generation module 600.

Signals input to the plurality of input channels of the signal transfer module may include voltages output from the plurality of semiconductor devices included in the signal generation module and a stage input voltage. The output channel of the signal transfer module may be configured to detect, based on the selection signal, a residual voltage corresponding to a portion of the stage input voltage that has not been converted into a partial digital code and output the detected residual voltage as a stage output voltage.

The analog-to-digital converter according to the present embodiment can efficiently achieve high resolution by stepwise performing digital conversion of an analog input signal through a plurality of conversion stages. Specifically, in a first conversion stage, digital conversion having a relatively large quantization interval is performed on the analog input signal, thereby rapidly determining an approximate magnitude of the input signal or upper-bit information. Thereafter, a remaining analog signal component that has not been converted by the digital conversion result generated in the first conversion stage, that is, a residual voltage, is generated, and the residual voltage is provided to a next conversion stage.

In the subsequent conversion stages, digital conversion having a smaller quantization interval than that of the previous conversion stage is performed using the residual voltage generated in the previous conversion stage as an input, thereby stepwise converting finer voltage information included in the analog input signal into digital form. In this manner, each conversion stage is configured to perform progressively refined digital conversion based on the digital conversion result determined in the previous stage, and partial digital codes generated in each stage are assigned to correspond to different bit weights. As a result, by combining the partial digital codes, a high-resolution digital code equivalent to that obtained by performing high-resolution conversion in a single stage is generated.

Accordingly, according to the fourth embodiment of the present invention, the resolution can be effectively improved without increasing circuit scale and power consumption, as compared with a case in which an analog input signal is converted with high resolution in a single stage. In particular, upper bits are rapidly determined in an initial conversion stage, and lower bits are precisely determined in subsequent conversion stages based on a residual voltage, thereby enabling analog-to-digital conversion that satisfies both high-speed operation and high resolution.

As described above, the analog-to-digital converter according to the fourth embodiment of the present invention performs digital conversion of an analog input signal stepwise through a plurality of conversion stages. In an initial stage, upper bits are coarsely converted, and in subsequent conversion stages, lower bits are finely converted based on a residual voltage, thereby improving overall resolution.

The analog-to-digital converter according to the fourth embodiment of the present invention is based on a basic structure of the pipeline-type analog-to-digital converter according to the second embodiment described above. The analog-to-digital converter according to the second embodiment is configured such that K bit processing units each determine one bit, thereby providing an overall resolution of K bits. In contrast, the analog-to-digital converter according to the fourth embodiment generalizes the structure of the second embodiment in that each conversion stage is configured to determine a plurality of bits.

### Fifth Embodiment

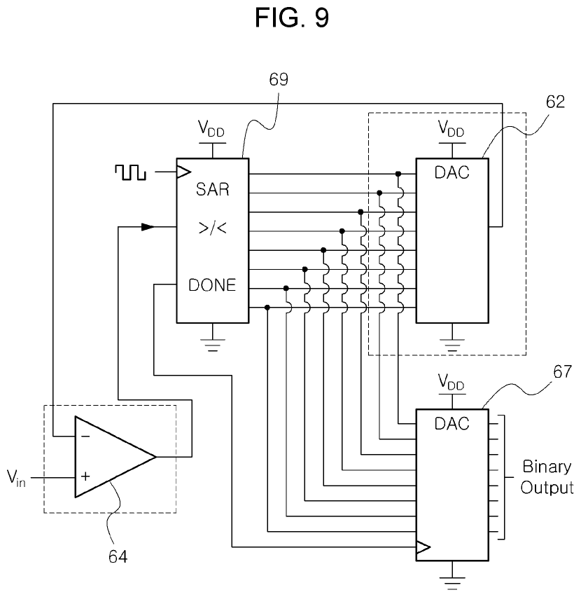

FIG. 9 is a circuit diagram illustrating a conventional SAR-type analog-to-digital converter. Referring to FIG. 9, a conventional Successive Approximation Register SAR type analog-to-digital converter includes a comparator 64, a digital-to-analog converter DAC 62, a SAR register 67, and a SAR control unit 69 in order to convert an input analog signal into a digital code. However, in conventional SAR ADCs, the comparator and the DAC are often implemented as relatively complex analog circuits composed of an operational amplifier, a capacitor array, a resistor network, and the like. Accordingly, problems such as an increase in circuit area, an increase in power consumption, and performance degradation due to process scaling may occur.

In order to address the above-described issues, a data converter according to a fifth embodiment of the present invention is an analog-to-digital converter based on SAR logic. The data converter based on SAR logic according to the present embodiment implements the functions of the comparator and the DAC using a structure including semiconductor devices having different threshold voltages or conductances. Specifically, the semiconductor devices are arranged to correspond to respective bit positions of a digital code, and threshold voltages corresponding to the bit positions are set such that a bit-level output signal is determined according to a relationship between an input analog signal and the threshold voltage.

Hereinafter, the structure and operation of a pipeline-type successive approximation data converter according to the fifth embodiment of the present invention will be described in detail with reference to the accompanying drawings. The successive approximation data converter according to the fifth embodiment of the present invention is an analog-to-digital converter that converts an analog signal into a digital code and outputs the digital code based on SAR logic and semiconductor devices sequentially connected in a pipeline form. Here, the digital code is composed of a binary code consisting of K bits (where K is a natural number).

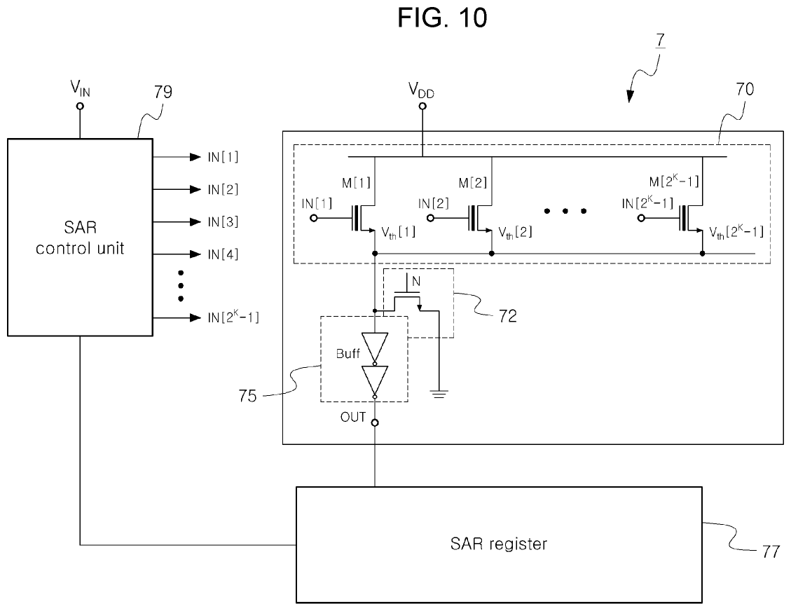

FIG. 10 is a circuit diagram illustrating an analog-to-digital converter based on SAR logic according to the fifth embodiment of the present invention. Referring to FIG. 10, the analog-to-digital converter 7 according to the fifth embodiment of the present invention includes a signal generation module 70, a signal conversion module 75, a SAR register 77, and a SAR control unit 79, and may further include a stabilization module 72.

The signal generation module 70 may include 2^{k}−1 semiconductor devices M[1], M[2], . . . , M[2^{k}−1]. The 2^{k}−1 semiconductor devices included in the signal generation module 70 are arranged in parallel between a power supply voltage V_{DD} and the signal conversion module 75. An input signal is applied to one selected semiconductor device among the semiconductor devices included in the signal generation module 70, and a bit-level output voltage corresponding to the input signal may be generated based on a relationship between the input signal and a threshold voltage.

Meanwhile, the 2^{k}−1 semiconductor devices included in the signal generation module 70 are configured to respectively receive control signals IN[1], IN[2], . . . , IN[2^{k}−1] provided from the SAR control unit 79. The SAR control unit 79 selects one of the semiconductor devices included in the signal generation module according to a preset SAR logic. Specifically, the SAR control unit 79 applies an input signal only to the selected semiconductor device through the control signals and applies a turn-off voltage to the remaining semiconductor devices. As a result, the signal generation module 70 generates and outputs a bit-level output voltage based on a relationship between the threshold voltage of the selected semiconductor device and the applied input signal.

The 2^{k}−1 semiconductor devices included in the signal generation module 70 each have different threshold voltages Vₜₕ or conductances. Accordingly, the semiconductor devices included in the signal generation module may be configured as semiconductor devices having non-volatile memory characteristics capable of varying threshold voltage or conductance, or may be composed of one of a flash memory device, a resistive change memory device, a phase-change memory device, a ferroelectric memory device, a magnetoresistive memory device, a field effect transistor FET, and a ferroelectric tunnel junction FTJ device. Since various methods for varying the threshold voltage or conductance of the semiconductor devices are substantially the same as those described in the first embodiment, a repeated description thereof will be omitted.

The signal conversion module 75 is configured to convert a bit-level output voltage output from the signal generation module 70 into a binary signal and to output a code of a corresponding bit in a digital code. The signal conversion module 75 may be configured as a device having a preset switching voltage, and may include one of an inverter circuit, a buffer circuit, and a sense amplifier, wherein the sense amplifier may be driven in a differential manner. Meanwhile, when the signal conversion module 75 is configured as an inverter circuit or a buffer circuit, performance of the analog-to-digital conversion may be improved by changing the number or structure of the inverters or by adjusting a channel width and a channel length of a MOSFET used in the inverter.

The stabilization module 72 may be composed of devices capable of providing a constant current to the signal generation module and may be disposed between an output terminal of the signal generation module and a ground terminal. The stabilization module 72 may be composed of one of a single MOSFET device, a plurality of MOSFET devices connected in series, a transmission gate device, a resistor, and a non-volatile memory device.

The SAR register 77 is a storage circuit configured to store and maintain each bit of a digital code generated during a successive approximation analog-to-digital conversion process, and may include a plurality of bit storage devices or a plurality of bit storage circuits. The SAR register 77 stores binary signals output from the signal conversion module on a bit-by-bit basis, and the stored bit values may be maintained or updated under the control of the SAR control unit. Accordingly, the SAR register stores the binary signals output from the signal conversion module at respective bit positions of the digital code and may sequentially record and maintain the bit values under the control of the SAR control unit.

The SAR control unit 79 may include one or more of a digital logic circuit, a flip-flop, a latch, a decoder, and a state machine. The SAR control unit 79 is a control circuit configured to generate and apply a plurality of control signals so that successive approximation analog-to-digital conversion is performed in hardware.

Specifically, the SAR control unit may sequentially generate bit control signals and control signals for selecting semiconductor devices in synchronization with a clock signal, thereby controlling the semiconductor devices included in the signal generation module to be selectively driven according to corresponding bit positions in the digital code. For this purpose, the SAR control unit 79 determines a semiconductor device to be selected in a next step according to a preset successive approximation logic by referring to bit values stored in the SAR register, and generates control signals for applying an input signal to the selected semiconductor device. In addition, the SAR control unit 79 is configured to provide an input voltage VIN to the selected semiconductor device and to provide a turn-off voltage to the remaining semiconductor devices that are not selected according to the control signals.

Through such control operations, the SAR control unit 79 sequentially applies the input signal to the semiconductor devices included in the signal generation module, thereby controlling the signal generation module to sequentially generate bit-level output voltages corresponding to the input signal.

Hereinafter, an operation of the successive approximation analog-to-digital converter according to the fifth embodiment having the above-described structure will be described.

First, in order to determine the most significant bit MSB of the digital code, the SAR control unit selects a semiconductor device having a threshold voltage corresponding to a midpoint of the entire range of the digital code according to a preset successive approximation logic. Accordingly, the SAR control unit applies the input signal to the selected semiconductor device through control signals and applies a turn-off voltage to the remaining semiconductor devices that are not selected.

At this time, when the input signal is greater than the threshold voltage of the selected semiconductor device, the corresponding semiconductor device is switched to a turn-on state and outputs a bit-level output voltage corresponding to a difference between the input signal and the threshold voltage. In contrast, when the input signal is not greater than the threshold voltage of the selected semiconductor device, the semiconductor device maintains a turn-off state, and the bit-level output voltage has a value of 0.

The signal conversion module receives the bit-level output voltage output from the signal generation module, and outputs a logic value ‘1’ when the bit-level output voltage exceeds a preset switching voltage, and outputs a logic value ‘0’ when the bit-level output voltage does not exceed the switching voltage. The binary value output from the signal conversion module is stored and maintained in the SAR register.

Meanwhile, the SAR control unit determines a bit position to be processed in a next step by referring to the bit value stored in the SAR register, and generates a control signal for selecting a semiconductor device corresponding thereto. Thereafter, the SAR control unit applies the input signal to the semiconductor device selected according to the control signal, and repeatedly performs a process of generating and determining the bit-level output voltage in the same manner as described above.

Through such a sequential bit determination process, a digital code corresponding to the input signal, which is an analog signal, is sequentially determined from a most significant bit to a least significant bit.

Hereinafter, in the successive approximation analog-to-digital converter according to the fifth embodiment, a method of programming and erasing threshold voltages of a plurality of semiconductor devices included in the signal generation module will be exemplarily described.

The plurality of semiconductor devices M[1:2^{k}−1] included in the signal generation module may be configured in a NOR-type array structure in which source terminals are commonly connected. In this case, drain terminals of the semiconductor devices may be connected to each other or may be individually separated. In both cases where the drain terminals are connected or separated, during a program or erase operation, a logic value ‘0’ is applied to the drain node and the source node, and a program voltage or an erase voltage is selectively applied to gate electrodes IN[1:2^{k}−1] of the semiconductor devices, thereby performing a program or erase operation of threshold voltages.

In addition, a configuration is also possible in which the drain node is maintained in a floating state and only a logic value ‘0’ is applied to the source node while the source node or the source node and a body are electrically connected. Even in this case, threshold voltages of the semiconductor devices may be programmed or erased according to a voltage applied to the gate electrodes. In this case, the logic value ‘0’ voltage applied to the source terminal may be applied through a common ground node N or may be provided through a separate voltage application path.

As described above, the converter according to the present embodiment may flexibly program and erase threshold voltages of the semiconductor devices included in the signal generation module by using the NOR-type array structure.

### Sixth Embodiment

The successive approximation data converter according to the sixth embodiment of the present invention is an analog-to-digital converter. The successive approximation data converter according to the sixth embodiment of the present invention is similar to the data converter according to the fifth embodiment described above, except that a plurality of semiconductor devices included in a signal generation module further include respective selection devices. Hereinafter, with reference to the accompanying drawings, a structure and operation of a pipeline-type successive approximation analog-to-digital converter according to the sixth embodiment of the present invention will be described in detail.

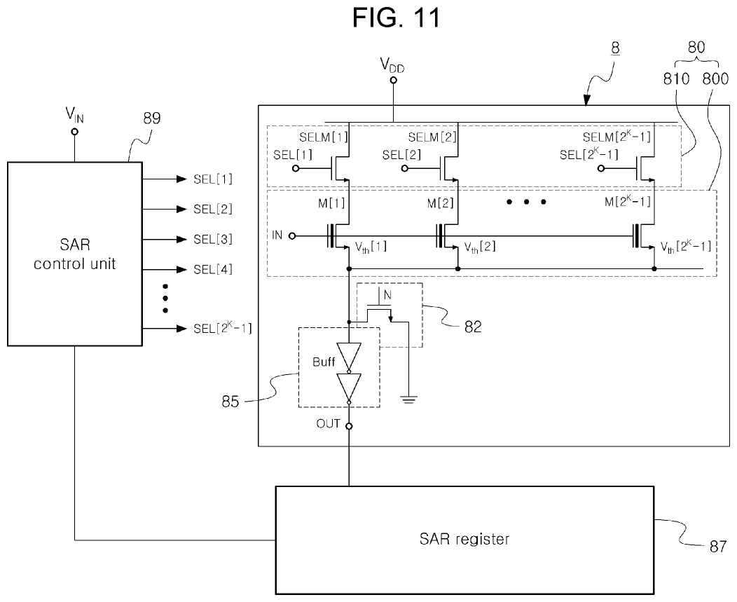

FIG. 11 is a circuit diagram illustrating a successive approximation analog-to-digital converter according to the sixth embodiment of the present invention. Referring to FIG. 11, the analog-to-digital converter 8 according to the sixth embodiment of the present invention includes a signal generation module 80, a signal conversion module 85, a SAR register 87, and a SAR control unit 89, and may further include a stabilization module 82. However, in the analog-to-digital converter according to the sixth embodiment, configurations and operations of the signal conversion module 85, the SAR register 87, and the stabilization module 82 are substantially the same as those of the signal conversion module 75, the SAR register 77, and the stabilization module 72 according to the fifth embodiment, and thus redundant descriptions thereof will be omitted.

The signal generation module 80 may include 2^{k}−1 semiconductor devices M[1:2^{k}−1] 800 and selection devices SELM[1:2^{k}−1] 810. The 2^{k}−1 semiconductor devices included in the signal generation module 80 are arranged in parallel between a power supply voltage V_{DD} and the signal conversion module 75. In addition, the 2^{k}−1 selection devices 810 included in the signal generation module 80 are respectively connected in series with the semiconductor devices in a one-to-one correspondence.

Configurations and operations of the 2^{k}−1 semiconductor devices M[1: 2^{k}−1] 800 included in the signal generation module 80 are substantially the same as those of the semiconductor devices according to the fifth embodiment, and thus redundant descriptions thereof will be omitted.

The 2^{k}−1 selection devices SELM[1: 2^{k}−1] 810 included in the signal generation module 80 may be configured as transmission gates TG or switching devices. The selection devices 810 are configured such that only the selection device connected to a selected semiconductor device is activated according to control signals from the SAR control unit.

The SAR control unit 89 according to the present embodiment applies an input voltage V_{IN} to all semiconductor devices 800 included in the signal generation module, selects a semiconductor device according to a preset successive approximation logic, and generates and outputs control signals SEL[1], SEL[2], . . . , SEL[2^{k}−1] for activating a selection device connected to the selected semiconductor device. Accordingly, the 2^{k}−1 selection devices SELM[1: 2^{k}−1]810 included in the signal generation module 80 may be selectively activated in response to the control signals SEL[1], SEL[2], . . . , SEL[2^{k}−1] from the SAR control unit 89.

Hereinafter, an operation of the successive approximation analog-to-digital converter according to the sixth embodiment of the present invention having the above-described configuration will be described.

First, in order to determine the most significant bit MSB of the digital code, the SAR control unit selects a semiconductor device having a threshold voltage corresponding to a midpoint of an entire range of the digital code according to a preset successive approximation logic. Accordingly, the input signal V_{IN} is applied to gate electrodes of all semiconductor devices included in the signal generation module, and the selection device connected to the selected semiconductor device is activated.

At this time, when the input signal is greater than the threshold voltage of the semiconductor device connected to the activated selection device, the corresponding semiconductor device is switched to a turn-on state and outputs a bit-level output voltage corresponding to a difference between the input signal and the threshold voltage. In contrast, when the input signal is not greater than the threshold voltage of the semiconductor device connected to the activated selection device, the semiconductor device maintains a turn-off state, and the bit-level output voltage has a value of 0. As described above, the converter according to the present embodiment is characterized by a structure in which semiconductor devices are selectively activated by using the selection devices.

The signal conversion module receives the bit-level output voltage output from the signal generation module and outputs a logic value ‘1’ when the bit-level output voltage exceeds a preset switching voltage, and outputs a logic value ‘0’ when the bit-level output voltage does not exceed the switching voltage. The binary value output from the signal conversion module is stored and maintained in the SAR register.

Meanwhile, the SAR control unit determines a bit position to be processed in a next step by referring to the bit value stored in the SAR register, and generates a control signal for selecting a semiconductor device corresponding thereto. Thereafter, the selection device connected to the semiconductor device selected according to the control signal is activated, and a process of generating and determining the bit-level output voltage in the same manner as described above is repeatedly performed.

Through such a sequential bit determination process, a digital code corresponding to the input signal, which is an analog signal, is sequentially determined from a most significant bit MSB to a least significant bit LSB.

Hereinafter, in the successive approximation analog-to-digital converter according to the sixth embodiment, a method of programming and erasing threshold voltages of a plurality of semiconductor devices included in the signal generation module will be exemplarily described.

When selection devices respectively connected to semiconductor devices included in the signal generation module are provided, program inhibition for unselected semiconductor devices may be performed using a channel self-boosting method. Specifically, a normal logic value ‘1’ is applied to drain terminals and gate electrodes of the selection devices SEL[1:k], and a high voltage is applied only to gate electrodes IN of the semiconductor devices, thereby boosting channel potentials of the unselected semiconductor devices so that programming is inhibited. In this case, a logic value ‘0’ is applied to source terminals of the semiconductor devices M[1:k], and a logic value ‘0’ is applied to a drain terminal of the selection device SEL[x] corresponding to the semiconductor device M[x] to be programmed.

In addition, a programming method using hot carrier injection may also be employed. In this case, a high voltage is applied to gate electrodes IN of the semiconductor devices, and a logic value ‘0’ is applied to a source terminal or a body of the semiconductor device M[x] to be programmed. In addition, a voltage for inducing hot carrier injection is applied to a drain terminal of the semiconductor device M[x], and a logic value ‘0’ is applied to drain terminals of the remaining semiconductor devices M[1: 2^{k}−1] that are not to be programmed, so that the threshold voltage programming operation is performed only for the selected semiconductor device.

As described above, the converter according to the present embodiment may precisely program and erase threshold voltages of semiconductor devices included in the signal generation module by selectively applying a channel self-boosting scheme using selection devices or a hot carrier injection scheme.

The analog-to-digital converter according to the sixth embodiment of the present invention adopts a structure in which semiconductor devices are selectively activated through selection devices, thereby facilitating circuit expansion as the number of semiconductor devices increases, and enabling relatively simple modification of a resolution (K bits) or structural variation.

In addition, the analog-to-digital converter according to the sixth embodiment of the present invention adopts a structure in which only a selected semiconductor device among a plurality of semiconductor devices is activated by using selection devices, thereby suppressing unnecessary current flow in unselected semiconductor devices. Accordingly, overall power consumption during a successive approximation conversion process may be effectively reduced.

Furthermore, in the analog-to-digital converter according to the sixth embodiment of the present invention, an input signal is commonly applied to gate electrodes of all semiconductor devices included in the signal generation module, and only a semiconductor device that actually operates is determined by the selection device. As a result, an input signal application path may be simplified, and design of control signals of the SAR control unit may be facilitated.

In particular, the analog-to-digital converters according to the fifth and sixth embodiments of the present invention have a structure in which semiconductor devices of the signal generation module are arranged in parallel. Accordingly, compared with a serially accumulated structure, wiring complexity is reduced and layout efficiency is improved, thereby effectively reducing an overall circuit area.

### Seventh Embodiment

The successive approximation data converter according to the seventh embodiment of the present invention is an analog-to-digital converter. The data converter according to the present embodiment is similar to the data converter according to the fifth embodiment described above, except that a plurality of semiconductor devices included in a signal generation module are connected in series to form a NAND string structure. Hereinafter, with reference to the accompanying drawings, a structure and operation of a pipeline-type successive approximation data converter according to the seventh embodiment of the present invention will be described in detail.

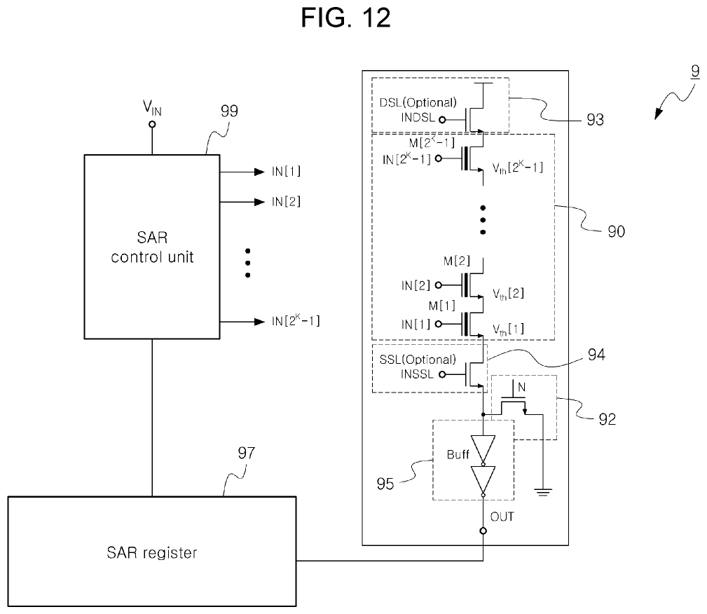

FIG. 12 is a circuit diagram illustrating a successive approximation analog-to-digital converter according to the seventh embodiment of the present invention. Referring to FIG. 12, the analog-to-digital converter 9 according to the seventh embodiment of the present invention includes a signal generation module 90, a signal conversion module 95, a SAR register 97, and a SAR control unit 99, and may further include a stabilization module 92. However, in the analog-to-digital converter according to the seventh embodiment, configurations and operations of the signal conversion module 95, the SAR register 97, the SAR control unit 99, and the stabilization module 92 are substantially the same as those of the signal conversion module 75, the SAR register 77, the SAR control unit 79, and the stabilization module 72 according to the fifth embodiment, and thus redundant descriptions thereof will be omitted.

The signal generation module 90 may include 2^{k}−1 semiconductor devices M[1], M[2], . . . , M[2^{k}−1]. The 2^{k}−1 semiconductor devices included in the signal generation module 90 are connected in series between a power supply voltage V_{DD} and the signal conversion module 95 and arranged in a NAND string configuration. Accordingly, an input signal is applied to one selected semiconductor device among the semiconductor devices included in the signal generation module 90, and a pass voltage is applied to the remaining semiconductor devices that are not selected, thereby generating a bit-level output voltage corresponding to the input signal based on a relationship between the input signal and a threshold voltage. Configurations and operations of the 2^{k}−1 semiconductor devices included in the signal generation module 90 are substantially the same as those of the semiconductor devices according to the fifth embodiment, and thus redundant descriptions thereof will be omitted.

Meanwhile, a drain select device (Drain Select Line; DSL) 92 and a source select device (Source Select Line; SSL) 93 may be further disposed at both ends of a string in which the semiconductor devices included in the signal generation module are connected in series. The DSL device and the SSL device may be used to perform selection control on a string basis or to perform program and erase operations of the semiconductor devices.

The SAR register 97 is a storage circuit configured to store and maintain each bit of a digital code generated during a successive approximation analog-to-digital conversion process and may include a plurality of bit storage elements. A structure and operation of the SAR register 97 according to the present embodiment are substantially the same as those of the SAR register according to the fifth embodiment, and thus redundant descriptions thereof will be omitted.

The SAR control unit 99 may include one or more of a digital logic circuit, a flip-flop, a latch, a decoder, or a state machine. The SAR control unit 99 is a control circuit configured to generate and apply a plurality of control signals so that the successive approximation analog-to-digital conversion is performed in hardware.

Specifically, the SAR control unit sequentially generates bit control signals and control signals for selecting semiconductor devices in synchronization with a clock signal, thereby controlling semiconductor devices included in the signal generation module to be selectively driven according to corresponding bit positions in a digital code. For this purpose, the SAR control unit 99 determines a semiconductor device to be selected in a next step according to a preset successive approximation logic by referring to bit values stored in the SAR register and generates control signals for applying an input signal to the selected semiconductor device. In addition, the SAR control unit 99 is configured to provide an input voltage VIN to the selected semiconductor device and to provide a pass voltage to the remaining semiconductor devices that are not selected according to the control signals.

Through such control operations, the SAR control unit 99 sequentially applies the input signal to the semiconductor devices included in the signal generation module, thereby controlling the signal generation module to sequentially generate bit-level output voltages corresponding to the input signal.

Hereinafter, in the successive approximation analog-to-digital converter according to the seventh embodiment, a method of programming and erasing a threshold voltage of an x-th semiconductor device M[x] among a plurality of semiconductor devices included in the signal generation module will be exemplarily described.

First, in a program operation, a logic value ‘0’ is applied to a drain terminal of the DSL device, and a normal logic value ‘1’ is applied to a gate electrode of the DSL device. A pass voltage is applied to gate electrodes of the semiconductor devices other than a selected semiconductor device M[x]. In addition, a pass voltage is applied to a gate electrode of the SSL device, and a logic value ‘0’ is applied to a source terminal of the SSL device. In this case, the ‘0’ voltage applied to the source terminal may be applied through a common ground node N or may be provided through a separate voltage application path. Under these conditions, a program electric field is formed in the selected semiconductor device M[x], so that a program operation is performed to change a threshold voltage of the corresponding semiconductor device.

Meanwhile, in an erase operation, in order to erase an entire string, an erase voltage is applied to a substrate, and a logic value ‘0’ is applied to gate electrodes of all semiconductor devices included in the string. Accordingly, all semiconductor devices in the string may be erased simultaneously. In addition, the erase operation is not limited to the entire string erase scheme. It is also possible to selectively erase semiconductor devices on a one-bit basis by using a gate-induced drain leakage GIDL phenomenon occurring in the SSL device or the DSL device.

As described above, the converter according to the present embodiment may flexibly program and erase threshold voltages of semiconductor devices included in the signal generation module on a string basis or on an individual device basis by using the DSL device and the SSL device. That is, the converter according to the present embodiment enables string-level selection control through the DSL device and the SSL device disposed at both ends of the string, and by using this structure, program and erase operations of the semiconductor devices may be performed. Accordingly, threshold voltages of the semiconductor devices of the signal generation module may be preset or calibrated.

In a conventional SAR logic-based converter, since the operation is performed sequentially on a bit-by-bit basis, the number of circuits simultaneously activated during an entire conversion process is limited. In contrast, the analog-to-digital converter according to the seventh embodiment of the present invention combines a NAND string-based signal generation module with a conventional SAR structure, thereby suppressing unnecessary dynamic power consumption and enabling low-power operation.

In addition, a NAND string structure, DSL/SSL configuration, and program/erase scheme applied to the analog-to-digital converter according to the seventh embodiment of the present invention have high similarity to structures and operating principles widely used in conventional NAND flash memory processes. Accordingly, the converter may be implemented using existing semiconductor manufacturing processes without requiring development of a separate new process.

Furthermore, the analog-to-digital converter according to the seventh embodiment of the present invention configures semiconductor devices of the signal generation module in a serially connected NAND string structure, thereby significantly improving device placement density compared to a parallel array structure. Accordingly, an overall circuit area may be effectively reduced while implementing the same resolution.

Moreover, the analog-to-digital converter according to the seventh embodiment of the present invention adopts a structure in which an input signal is applied to a selected semiconductor device and a pass voltage is applied to semiconductor devices that are not selected, thereby eliminating a need to form complex selection wiring for each individual device. Accordingly, a control signal structure of the SAR control unit may be simplified and wiring complexity may be reduced.

Although the present invention has been described above with reference to preferred embodiments, these embodiments are merely illustrative and do not limit the present invention. Those skilled in the art will appreciate that various modifications and applications not exemplified above may be made without departing from the essential characteristics of the present invention. Differences related to such modifications and applications should be interpreted as being included within the scope of the present invention as defined by the appended claims.

What is claimed is:

1. A pipeline-type data converter configured to convert an analog signal into a digital code composed of K bits (where K is a natural number) or to convert a digital code into an analog signal based on semiconductor devices, the data converter comprising:
K bit processing units configured to correspond one-to-one with K bits constituting the digital code and sequentially connected in a pipeline structure,
wherein each of the bit processing units comprises:
a signal generation module including a semiconductor device having a threshold voltage or conductance set according to a position of a corresponding bit in the digital code, the signal generation module configured such that a bit-level input voltage is applied to the semiconductor device and a bit-level residual voltage B_RES determined based on a relationship between the bit-level input voltage B_IN and a threshold voltage Vₜₕ of the semiconductor device is generated; and
a signal transfer module including one or more switching devices and configured to output one of the bit-level input voltage and the bit-level residual voltage of the signal generation module as a bit-level output voltage according to an output selection signal,
wherein a bit-level input voltage of a bit processing unit processing a most significant bit MSB of the digital code is a preset initial voltage or an analog signal to be converted, and
wherein bit-level input voltages of remaining bit processing units are bit-level output voltages of signal transfer modules included in bit processing units of a previous stage.

2. The pipeline-type data converter according to claim 1, wherein the data converter is a digital-to-analog converter DAC configured to convert a digital code into an analog signal,
wherein the bit-level input voltage of a bit processing unit processing a most significant bit MSB of the digital code is a preset initial voltage,
wherein the signal transfer module of each bit processing unit is configured such that a code corresponding to a respective bit of the digital code or an inverted code thereof is provided as the output selection signal, and
wherein a bit-level output voltage of the signal transfer module of a bit processing unit processing a least significant bit LSB of the digital code forms an analog signal corresponding to the digital code.

3. The pipeline-type data converter according to claim 1, wherein the data converter is an analog-to-digital converter ADC configured to convert an analog signal into a digital code,
wherein each of the bit processing units further comprises:
a signal conversion module configured to convert a bit-level residual voltage B_RES output from the signal generation module into a binary signal and output the binary signal,
wherein a bit-level input voltage of a bit processing unit processing a most significant bit MSB of the digital code is the analog signal, and
wherein the signal conversion module of each bit processing unit is configured to output a code corresponding to a respective bit of the digital code and to provide the code to the signal transfer module as the output selection signal.

4. The pipeline-type data converter according to claim 1, wherein the data converter is configured to selectively operate as one of an analog-to-digital converter ADC and a digital-to-analog converter DAC,
wherein each of the bit processing units further comprises:
a signal conversion module configured to convert a bit-level residual voltage output from the signal generation module into a binary signal and output the binary signal; and
a mode selection module disposed between the signal conversion module and the signal transfer module and configured to receive an operation mode selection signal and to control a signal path according to the received operation mode selection signal so that the converter operates as one of the ADC and the DAC,
wherein the mode selection module is configured to provide an output signal of the signal conversion module corresponding to an analog signal to be converted as the output selection signal to the signal transfer module when an analog-to-digital conversion mode is selected, and
wherein the mode selection module is configured to provide a code corresponding to a respective bit of a digital code to be converted as the output selection signal to the signal transfer module when a digital-to-analog conversion mode is selected.

5. The pipeline-type data converter according to claim 1, wherein each of the bit processing units further comprises:
a stabilization module configured as a device or circuit for providing a constant current to the signal generation module and disposed between an output terminal of the signal generation module and a ground terminal.

6. The pipeline-type data converter according to claim 1, wherein the signal generation module of the bit processing unit comprises a semiconductor device having nonvolatile memory characteristics capable of varying a threshold voltage or conductance, or comprises one selected from the group consisting of a flash memory device, a resistive random-access memory device, a phase-change memory device, a ferroelectric memory device, a magnetoresistive memory device, and a field-effect transistor.

7. The pipeline-type data converter according to claim 3, wherein the signal conversion module of the bit processing unit comprises one selected from the group consisting of an inverter circuit, a buffer circuit, and a sense amplifier having a preset switching voltage.

8. The pipeline-type data converter according to claim 1, wherein the signal transfer module comprises:
a first switching device configured to output the bit-level residual voltage of the signal generation module as the bit-level output voltage;
a second switching device configured to output the bit-level input voltage of the bit processing unit as the bit-level output voltage; and
a selection circuit configured to drive one of the first switching device and the second switching device according to the output selection signal,
wherein the output selection signal of the selection circuit is one of a code corresponding to a respective bit of the digital code and a binary signal obtained by converting the bit-level residual voltage of the signal generation module.

9. The pipeline-type data converter according to claim 8, wherein the first switching device and the second switching device of the signal transfer module comprise one selected from the group consisting of a transmission gate TG and a single pass gate.

10. The pipeline-type data converter according to claim 4, wherein the mode selection module is configured to include one selected from the group consisting of a digital multiplexer, an analog multiplexer, and a tri-state buffer, or a combination of a plurality of NAND gate devices.

11. The pipeline-type data converter according to claim 1, wherein the data converter further comprises a threshold voltage adjustment module configured to adjust or reset threshold voltages of memory devices included in the signal generation modules of the bit processing units.

12. A pipeline-type data converter based on semiconductor devices and configured to convert an analog signal into a digital code composed of K bits (where K is a natural number), the data converter comprising:
a plurality of conversion stages configured to convert a stage input voltage into a digital code to generate a partial digital code and sequentially connected in a pipeline structure; and
an output code generation module configured to generate a final digital code corresponding to the analog signal based on the partial digital codes output from the plurality of conversion stages,
wherein each of the conversion stages comprises:
a signal generation module configured to generate the partial digital code by converting the stage input voltage into a digital code using semiconductor devices having mutually different threshold voltages or conductances; and
a signal transfer module configured to generate a stage output voltage based on the stage input voltage and a digital conversion result of the signal generation module,
wherein a stage input voltage of a first conversion stage is the analog signal to be converted, and
wherein stage input voltages of remaining conversion stages are stage output voltages generated from conversion stages of a previous stage.

13. The pipeline-type data converter according to claim 12, wherein the partial digital code generated by the signal generation module of each conversion stage is configured as a thermometer code,
wherein each of the conversion stages further comprises a code conversion module configured to convert the partial digital code in the form of the thermometer code generated from the signal generation module into a binary code and output the binary code, and
wherein the output code generation module is configured to generate the final digital code based on binary codes output from the code conversion modules included in the plurality of conversion stages.

14. The pipeline-type data converter according to claim 12, wherein the stage output voltage is a residual voltage corresponding to a portion of the stage input voltage that is not converted by the partial digital code in the signal generation module included in the corresponding conversion stage.

15. The pipeline-type data converter according to claim 12, wherein the signal generation module included in the conversion stage comprises a plurality of semiconductor devices having mutually different threshold voltages or conductances,
wherein the stage-level voltage is applied to the plurality of semiconductor devices, and the plurality of semiconductor devices are configured to generate respective binary values based on a relationship between the stage-level voltage and the threshold voltage, and
wherein the signal generation module is configured to generate the partial digital code based on the binary values respectively generated by the plurality of semiconductor devices.

16. The pipeline-type data converter according to claim 12, wherein the signal generation module included in the conversion stage is configured as a semiconductor device having nonvolatile memory characteristics capable of varying a threshold voltage or conductance, or comprises one selected from the group consisting of a flash memory device, a resistive random-access memory device, a phase-change memory device, a ferroelectric memory device, a magnetoresistive memory device, and a field-effect transistor FET.

17. The pipeline-type data converter according to claim 12, wherein the signal transfer module included in the conversion stage comprises one selected from the group consisting of a digital multiplexer, an analog multiplexer, and a tri-state buffer configured to select one of a plurality of input channels according to a selection signal and to provide the selected input channel to a single output channel,
wherein the selection signal is the partial digital code according to a digital conversion result of the signal generation module,
wherein signals input to the plurality of input channels include voltages respectively output from a plurality of semiconductor devices included in the signal generation module and the stage input voltage, and
wherein the output channel is configured to detect, based on the selection signal, a residual voltage corresponding to a portion of the stage input voltage that is not converted by the partial digital code and output the detected residual voltage as the stage output voltage.

18. A successive approximation register SAR type data converter based on semiconductor devices and configured to convert an analog signal as an input signal into a digital code composed of K bits (where K is a natural number), the data converter comprising:
a signal generation module including a plurality of semiconductor devices arranged to correspond to respective bits of the digital code and having mutually different threshold voltages, wherein the signal generation module is configured such that the input signal is applied to a selected one of the semiconductor devices and a bit-level output voltage corresponding to the input signal is generated based on a relationship between the input signal and the threshold voltage;
a signal conversion module configured to convert the bit-level output voltage output from the signal generation module into a binary signal and output a binary value corresponding to a respective bit of the digital code;
a SAR register configured to store the binary value output from the signal conversion module at a corresponding bit position of the digital code; and
a SAR control unit configured to generate, according to a preset successive approximation logic, control signals for sequentially selecting the semiconductor devices included in the signal generation module based on bit values stored in the SAR register,
wherein, according to the control signals of the SAR control unit, the input signal is sequentially applied to the semiconductor devices included in the signal generation module such that the signal generation module sequentially generates bit-level output voltages corresponding to the input signal.

19. The successive approximation type data converter according to claim 18, wherein the semiconductor devices included in the signal generation module are connected in parallel,
wherein, according to the control signals of the SAR control unit, the input signal is applied only to a selected semiconductor device and a turn-off signal is applied to remaining semiconductor devices that are not selected, and
wherein the bit-level output voltage of the signal generation module is generated based on a relationship between the threshold voltage of the selected semiconductor device and the applied input signal.

20. The successive approximation type data converter according to claim 18, wherein the semiconductor devices included in the signal generation module are connected in series to form a string structure,
wherein, according to the control signals of the SAR control unit, the input signal is applied to a selected semiconductor device and a pass voltage is applied to remaining semiconductor devices that are not selected, and
wherein a bit-level output voltage of the signal generation module is generated based on a relationship between the threshold voltage of the selected semiconductor device and the applied input signal.

21. The successive approximation type data converter according to claim 18, wherein the successive approximation type data converter further comprises:
a stabilization module including devices configured to provide a constant current to the semiconductor devices included in the signal generation module and disposed between an output terminal of the signal generation module and a ground terminal.

22. The successive approximation type data converter according to claim 18, wherein the semiconductor devices included in the signal generation module comprise semiconductor devices having nonvolatile memory characteristics capable of varying a threshold voltage or conductance, or comprise one selected from the group consisting of a flash memory device, a resistive random-access memory device, a phase-change memory device, a ferroelectric memory device, a magnetoresistive memory device, a field-effect transistor FET, and a ferroelectric tunnel junction device.

23. The successive approximation type data converter according to claim 18, wherein the signal conversion module comprises one selected from the group consisting of an inverter circuit, a buffer circuit, and a sense amplifier having a preset switching voltage.

24. The successive approximation type data converter according to claim 18, wherein the signal generation module further comprises a plurality of selection devices respectively connected in one-to-one correspondence with the plurality of semiconductor devices.

25. The successive approximation type data converter according to claim 24, wherein the SAR control unit is configured to apply the input signal to the plurality of semiconductor devices included in the signal generation module and to sequentially activate the selection devices connected to the semiconductor devices selected according to the control signals, such that the signal generation module sequentially outputs bit-level output voltages corresponding to the input signal.

26. The successive approximation type data converter according to claim 24, wherein the selection devices of the signal generation module comprise one selected from the group consisting of a transmission gate TG and a switching device.
